(19) United States
(12) Patent Application Publication
(10) Pub. No.: US 2025/0157879 A1
(43) Pub. Date: May 15, 2025

(54) SEMICONDUCTOR APPARATUS

(71) Applicant: SAMSUNG ELECTRONICS CO., LTD., Suwon-si (KR)

(72) Inventors: Dongkyun KIM, Suwon-si (KR); Sungchan KANG, Suwon-s (KR); Daehyuk SON, Suwon-si (KR); Hotaik LEE, Suwon-si (KR); Seogwoo HONG, Suwon-si (KR)

(73) Assignee: SAMSUNG ELECTRONICS CO., LTD., Suwon-si (KR)

(21) Appl. No.: 18/746,857

(22) Filed: Jun. 18, 2024

(30) Foreign Application Priority Data
Nov. 14, 2023 (KR) 10-2023-0157694

(51) Int. Cl. H01L 23/427

(52) U.S. Cl. CPC H01L 23/427

(57) ABSTRACT

A semiconductor apparatus includes a semiconductor chip including a semiconductor integrated circuit, a cooling channel at least partially in the semiconductor chip and including a fine pattern on at least a portion of a wall surface of the cooling channel, the fine pattern configured to generate a capillary pressure that induces a flow of a liquid coolant, and a temperature controller configured to control a supply temperature of the liquid coolant supplied to the cooling channel.

### CROSS-REFERENCE TO RELATED APPLICATION

This application is based on and claims priority under 35 U.S.C. § 119 to Korean Patent Application No. 10-2023-0157694, filed on Nov. 14, 2023 in the Korean Intellectual Property Office, the disclosure of which is incorporated by reference herein in its entirety.

### BACKGROUND

### 1. Field

The disclosure relates to a semiconductor apparatus.

### 2. Description of Related Art

To remove heat generated by electronic devices, air cooling devices have been mainly used. As the power density of electronic devices increases, the use of liquid cooling devices is increasing to address the increased amount of heat generation. Moreover, in the case of data centers, interest in high-efficiency next-generation cooling methods such as liquid cooling is gradually increasing to reduce the amount of power used. Liquid cooling methods may include a single-phase liquid cooling method in which a coolant is not phase changed according to a temperature range of a heat generating portion, and a two-phase liquid cooling method in which the coolant is phase changed. The two-phase liquid cooling method may cover a wider range of a heat generation amount than the single-phase liquid cooling method.

### SUMMARY

Provided is a semiconductor apparatus with a two-phase liquid cooling structure.

Further provided is a semiconductor apparatus having a high heat exchange efficiency by controlling a temperature of a liquid coolant supplied to a cooling channel.

Additional aspects will be set forth in part in the description which follows and, in part, will be apparent from the description, or may be learned by practice of the presented embodiments of the disclosure.

According to an aspect of the disclosure, a semiconductor apparatus may include a semiconductor chip including a semiconductor integrated circuit, a cooling channel at least partially in the semiconductor chip and including a fine pattern on at least a portion of a wall surface of the cooling channel, the fine pattern configured to generate a capillary pressure that induces a flow of a liquid coolant, and a temperature controller configured to control a supply temperature of the liquid coolant supplied to the cooling channel.

The temperature controller may include a heating element configured to preheat the liquid coolant supplied to the cooling channel.

The temperature controller may include a first control element configured to detect a temperature of the liquid coolant supplied to the cooling channel, and based on the temperature of the liquid coolant being less than or equal to a predefined temperature, preheat the liquid coolant.

The first control element may include a resistance temperature sensor.

The temperature controller may include a second control element configured to detect a temperature of the semiconductor integrated circuit.

The temperature controller may be further configured to preheat the liquid coolant supplied to the cooling channel based on the temperature of the semiconductor integrated circuit detected by the second control element being greater than or equal to a critical temperature.

The critical temperature may correspond to a boiling point temperature of the liquid coolant.

The temperature controller may be further configured to heat the liquid coolant until the temperature of the liquid coolant supplied to the cooling channel reaches the critical temperature.

The semiconductor apparatus may include a liquid channel region in a region of the cooling channel where the fine pattern is formed, the liquid channel region being configured as a passage for the liquid coolant, and a vapor channel region in a remaining region of the cooling channel where the fine pattern is not formed, the vapor channel region configured as a passage for a vapor coolant.

The semiconductor apparatus may include a package housing at least partially surrounding the semiconductor chip, where the package housing may include a first opening configured to discharge the vapor coolant from the cooling channel and at least one second opening configured to supply the liquid coolant to the cooling channel.

The semiconductor apparatus may include a vapor chamber disposed on the semiconductor chip and including at least a portion of the fine pattern for forming the cooling channel.

The vapor chamber may expose at least a portion of the semiconductor chip to the cooling channel.

The temperature controller may be disposed between the semiconductor chip and the vapor chamber.

According to an aspect of the disclosure, a semiconductor apparatus may include a semiconductor chip including a semiconductor integrated circuit, a plurality of cooling channels at least partially in the semiconductor chip, each of the plurality of cooling channels including a fine pattern on at least a portion of a wall surface of a respective cooling channel of the plurality of cooling channels, each of the fine patterns being configured to generate a capillary pressure that induces a flow of a liquid coolant, and a temperature controller configured to control a supply temperature of the liquid coolant supplied to the plurality of cooling channels.

The semiconductor apparatus may include a package housing at least partially surrounding the semiconductor chip, the package housing including at least one first opening configured to discharge vapor coolant and a plurality of second openings respectively corresponding to the plurality of cooling channels and configured to apply the liquid coolant to respective cooling channels of the plurality of cooling channels.

According to an aspect of the disclosure, a method of controlling a temperature of a liquid coolant supplied to a cooling channel in a semiconductor chip, the cooling channel including a fine pattern configured to generate a capillary pressure that induces a flow of the liquid coolant, may include detecting, by a first control element of a temperature controller, the temperature of the liquid coolant supplied to the cooling channel, and controlling, by the temperature controller, the temperature of the liquid coolant supplied to the cooling channel.

The method may include, prior to the detecting the temperature of the liquid coolant, detecting, by a second control element of the temperature controller, whether a temperature of the semiconductor chip greater than or equal to a critical temperature.

The controlling the temperature of the liquid coolant may include preheating, by the first control element, the liquid coolant supplied to the cooling channel.

The preheating the liquid coolant may include preheating, by the first control element, the liquid coolant such that the temperature of the liquid coolant supplied to the cooling channel reaches the critical temperature.

The critical temperature may correspond to a boiling point temperature of the liquid coolant.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a diagram illustrating a semiconductor apparatus according to an embodiment;

FIG. 2 is a diagram illustrating a cooling channel according to an embodiment;

FIG. 3 is a diagram illustrating a semiconductor apparatus according to an embodiment;

FIGS. 4A to 4C are plan views illustrating a fine pattern according to an embodiment;

FIGS. 5A and 5B are plan views illustrating a cooling channel and a fine pattern according to an embodiment;

FIG. 6 is a diagram illustrating a semiconductor apparatus according to an embodiment;

FIG. 7A is a diagram illustrating heat transfer by partial boiling of a liquid coolant supplied in an unsaturated state according to an embodiment;

FIG. 7B is a diagram illustrating heat transfer by saturated boiling of a liquid coolant supplied in a saturated state according to an embodiment;

FIG. 8 is a graph illustrating a heat exchange efficiency of a liquid coolant that exchanges heat in an unsaturated state and a saturated state according to an embodiment;

FIG. 9 is a diagram illustrating a semiconductor apparatus according to an embodiment;

FIG. 10 is a diagram illustrating a control element according to an embodiment;

FIG. 11 is a diagram illustrating a semiconductor apparatus according to an embodiment;

FIG. 12 is a diagram illustrating a semiconductor apparatus according to an embodiment;

FIG. 13 is a diagram illustrating a semiconductor apparatus according to an embodiment;

FIG. 14 is a diagram illustrating a semiconductor apparatus according to an embodiment;

FIGS. 15A and 15B are diagrams illustrating portions a device for verifying an effect of a semiconductor apparatus according to an embodiment;

FIG. 16 is a graph illustrating results obtained by using the device of FIGS. 15A and 15B according to an embodiment;

FIG. 17 is a flowchart illustrating a method of controlling a temperature of a liquid coolant in a semiconductor apparatus according to an embodiment; and

FIG. 18 is a flowchart illustrating a method of controlling a temperature of a liquid coolant in a semiconductor apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments will be described in detail with reference to the accompanying drawings. The embodiments described below are merely exemplary, and various modifications are possible from these embodiments. In the following drawings, the same reference numerals refer to the same components, and the size of each component in the drawings may be exaggerated for clarity and convenience of description. The embodiments described below are merely exemplary, and various modifications are possible from these embodiments.

In the following description, when a component is referred to as being “above” or “on” another component, it may be directly on an upper, lower, left, or right side of the other component while making contact with the other component or may be above an upper, lower, left, or right side of the other component without making contact with the other component.

Singular expressions include plural expressions unless the context clearly dictates otherwise. Terms such as first, second, etc. may be used to describe various components, but are used only for the purpose of distinguishing one component from another component. These terms do not limit the difference in the material or structure of the components. The use of the term “the” and similar designating terms may correspond to both the singular and the plural.

In addition, when a certain part “includes” a certain component, it means that other components may be further included rather than excluding other components unless otherwise stated.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In addition, terms such as “unit” and “module” described in the specification may indicate a unit that processes at least one function or operation, and this may be implemented as hardware or software, or may be implemented as a combination of hardware and software.

Connections or connection members of lines between components illustrated in the drawings exemplarily represent functional connections and/or physical or circuit connections, and in actual devices, may be represented as replaceable or additional various functional connections, physical connections, and circuit connections. The use of all examples or exemplary terms is simply for explaining a technical idea in detail, and the scope is not limited by these examples or exemplary terms unless limited by the claims.

To address a cooling disadvantage that is a factor of limiting the performance of electronic devices including semiconductor chips, an efficient cooling system may be required. In the case of a semiconductor apparatus to which a high performance computing (HPC) field and a stacked three-dimensional (3D) semiconductor chip are applied, a cooling system capable of addressing an increase of a power density, an increase of a heat generation amount due to high integration, etc. may be required. To meet these demands, a two-phase liquid cooling system capable of utilizing a latent heat of evaporation of a coolant may be applied to the semiconductor apparatus. A two-phase liquid cooling method may include immersion cooling, spray cooling, jet impingement cooling, etc.

According to a two-phase liquid cooling system of the disclosure, at least a portion of a cooling channel serving as a passage for a coolant may be formed inside an object to be cooled. In other words, the cooling channel may be wholly formed inside the object to be cooled, and may be recessed inward from a surface (for example, upper surface) of the object to be cooled. The object to be cooled may be, for example, a semiconductor chip (i.e., integrated circuit die). A cross-sectional region of the cooling channel may include a liquid flow path region having a fine pattern forming a capillary pressure to allow a liquid coolant to flow, and a vapor flow path region not having a capillary structure to allow a vapor coolant to flow. The liquid flow path region and the vapor flow path region may not be divided physically, and may be distinguished by the presence or absence of the fine pattern. In the liquid flow path region, the liquid coolant may absorb heat from a heat surface adjacent to a heat source and be vaporized to be a vapor. According to some embodiments, a bubble generated in the liquid flow path region may be moved to the vapor flow path region, and be discharged outside the object to be cooled along the vapor flow path region. A region from which the bubble escapes in the liquid flow path region may be filled with the liquid coolant by the capillary pressure. According to some embodiments, since the bubble is easily separated from the heat surface, a cooling efficiency may be improved and the generation of a hot spot may be reduced or prevented. Also, the fine pattern may increase an area of heat exchange with the liquid coolant, and may facilitate a heat exchange with the heat source. Also, since the liquid coolant flows along the liquid flow path region by the capillary pressure, a coolant supply such as a high-capacity pump, etc. for supplying the liquid coolant to the cooling channel is not required, such that a cost of the cooling system may be reduced and a power consumption may be reduced. The semiconductor apparatus to which the two-phase liquid cooling system may be applied will be described. However, the two-phase liquid cooling system may not necessarily be applied to the semiconductor apparatus described below.

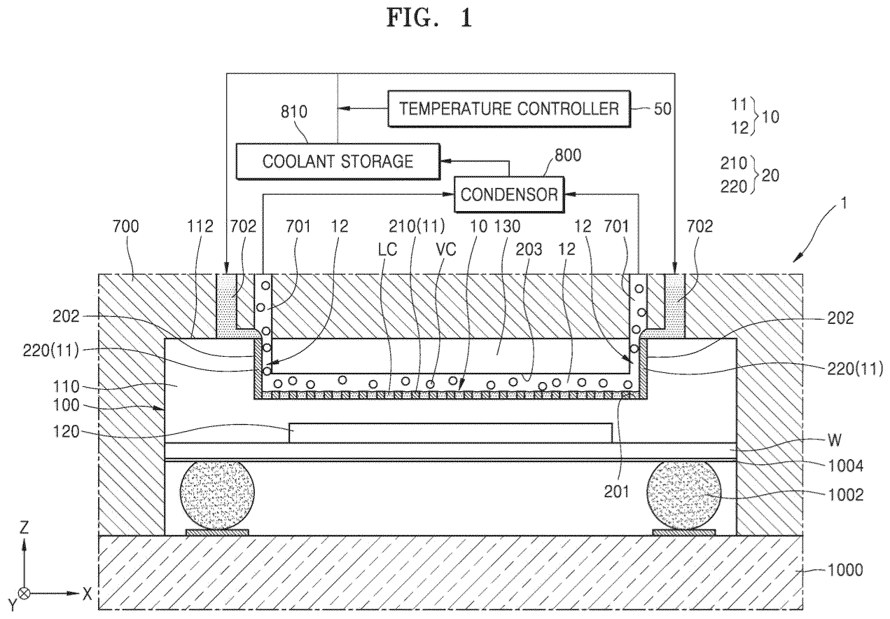

FIG. 1 is a diagram illustrating a semiconductor apparatus according to an embodiment.

Referring to FIG. 1, the semiconductor apparatus 1 may include a semiconductor chip 100 and a cooling channel 10. The cooling channel 10 may include a two-phase liquid cooling structure. The semiconductor chip 100 may include a substrate 110 and a semiconductor integrated circuit 120 formed on a surface of the substrate 110. The semiconductor chip 100 may include a variety of semiconductor integrated circuit 120 chips. For example, the semiconductor chip 100 may include a memory chip including a memory integrated circuit, a logic chip including a logic integrated circuit, a central processing unit (CPU) chip, a graphic processing unit (GPU) chip, an application specific integrated circuit (ASIC) chip, etc. To implement the semiconductor apparatus 1 of a small form factor, the semiconductor chip 100 may include a semiconductor integrated circuit 120 chip of a wafer level. The substrate 110 may include a wafer. The semiconductor chip 100 may be, for example, mounted on a printed circuit board 1000 by using solder balls 1002. A wiring layer 1004 for electrical connection between the semiconductor integrated circuit 120 and the printed circuit board 1000 may be provided on a lower surface of the semiconductor chip 100. The wiring layer 1004 is electrically passivated from the outside. The semiconductor chip 100 may be referred to as an integrated circuit die, and a device including the integrated circuit die may be referred to as an integrated circuit device.

At least a portion of the cooling channel 10 of the semiconductor apparatus 1 according to some embodiments may be formed inside the semiconductor chip 100 (for example, inside the substrate 110). In other words, the cooling channel 10 may be wholly formed inside the semiconductor chip 100 (for example, inside the substrate 110), communicate with the outside, and may be recessed inward from an upper surface 112 of the semiconductor chip 100 (for example, an upper surface 112 of the substrate 110). A fine pattern 20 that generates a capillary pressure inducing a flow of a liquid coolant LC may be provided on at least a portion of a wall surface of the cooling channel 10. By this, a passage (liquid channel region 11) for a liquid coolant LC may be formed in a region of the cooling channel 10 where the fine pattern 20 is formed, and a passage (vapor channel region 12) for a vapor coolant VC may be formed in a remaining region of the cooling channel 10 where a capillary structure is not formed. The cooling channel 10 may be connected to a condenser 800 and a coolant storage 810. By this, a two-phase liquid cooling system may be implemented.

In the semiconductor chip 100 according to some embodiments, the cooling channel 10 may be formed to include the liquid channel region 11 through which the liquid coolant LC moves, and the vapor channel region 12 which communicates with the liquid channel region 11 and through which the vapor coolant VC moves. That is, the cross-sectional region of the cooling channel 10 may include the liquid channel region 11 and the vapor channel region 12. The liquid coolant LC may be effectively moved inside the semiconductor chip 100 along the liquid channel region 11 by the capillary pressure generated by the fine pattern 20 within the cooling channel 10. The liquid coolant LC of the liquid channel region 11 may absorb heat from a heat source of the semiconductor chip 100 (for example, from the semiconductor integrated circuit 120) and be vaporized to be a vapor coolant VC. The vapor coolant VC may move from the liquid channel region 11 to the vapor channel region 12. A space from which the vapor coolant VC escapes in the liquid channel region 11 may be filled with the liquid coolant LC by the capillary pressure. The vapor coolant VC may move to the condenser 800 along the vapor channel region 12. The vapor coolant VC may be liquefied into a liquid coolant LC in the condenser 800 and then be moved to the coolant storage 810.

The semiconductor apparatus 1 according to some embodiments may effectively cool the semiconductor chip 100 because the liquid coolant LC may be supplied to a location close to the internal heat source of the semiconductor chip 100. When the liquid coolant LC is vaporized near the heat source, the vapor coolant VC may escape to the vapor flow path region. An empty space, from which the vapor coolant VC has escaped, of the liquid flow path region may be quickly filled with the liquid coolant LC that is introduced from the surroundings due to a capillary phenomenon of the fine pattern 20. The vapor coolant VC may move to the condenser 800 through the vapor channel region 12. Therefore, the liquid coolant LC may be quickly and continuously supplied around the heat source, thereby reducing a thermal resistance near the heat source. In other words, a disadvantage of forming a vapor film on a surface of the cooling channel 10 near the heat source may be reduced or eliminated, thereby uniformly maintaining cooling performance, suppressing the generation of a hot spot, and effectively dispersing heat. Also, since the liquid coolant LC moves by the capillary pressure generated by the fine pattern 20, a pump or similar components for moving the liquid coolant LC may be omitted, thereby reducing the power consumption of the cooling system. Since an area of a heat transfer surface is increased by the fine pattern 20, an efficiency of heat transfer from the semiconductor chip 100 to the liquid coolant LC may be improved, and since a vapor coolant VC bubble is effectively removed from the heat transfer surface 101, critical heat flux (CHF) performance may be improved. Also, since the liquid coolant LC is moved by the capillary pressure, the liquid coolant LC may not be affected by a posture of the semiconductor chip 100. In other words, although the integrated circuit device shown in FIG. 1 is applied to the electronic device in an upright or inverted state, the liquid channel region 11 and the vapor channel region 12 may remain the same, and the liquid coolant LC may move along the liquid channel region 11, and the vapor coolant VC may move along the vapor channel region 12.

The cooling channel 10 and the fine pattern 20 according to some embodiments may be formed on the semiconductor chip 100 (for example, the substrate 110). The substrate 110 may include a wafer W on which the semiconductor integrated circuit 120 is formed through a semiconductor process. After the semiconductor integrated circuit 120 is formed on a surface (for example, a lower surface (or active surface)) of the substrate 110 through a semiconductor process, the cooling channel 10 may be formed to be immersed from the other surface (for example, an upper surface 112 (or inactive surface)) of the substrate 110 through a semiconductor process such as etching. Also, the fine pattern 20 may be formed on at least a portion of a wall surface of the cooling channel 10 through a semiconductor process such as etching or laser ablation. In this way, a structure for cooling may be formed in a manufacturing process of the semiconductor chip 100, such that the semiconductor apparatus 1 including the cooling structure may be easily manufactured.

The liquid coolant LC may move along the liquid channel region 11 by the capillary pressure generated by the fine pattern 20. In some embodiments, the liquid coolant LC does not exist in the vapor channel region 12. By this, the vapor coolant VC may be effectively discharged outside the semiconductor chip 100 along the vapor channel region 12. However, the liquid coolant LC may partially exist in the vapor channel region 12 due to a disturbance such as vibration.

The cooling channel 10 may be formed inside the semiconductor chip 100 (for example, the substrate 110). The wall surface of the cooling channel 10 may include a first wall surface 201, a second wall surface 202, and a third wall surface 203. The first wall surface 201 may include a wall surface in a transverse direction that is immersed from an upper surface of the semiconductor chip 100 (e.g., the substrate 110) and is close to the semiconductor integrated circuit 120. That is, the first wall surface 201 may include a bottom surface of the cooling channel 10. The second wall surface 202 may include a side wall surface extending in a longitudinal direction from the first wall surface 201 toward the upper surface of the substrate 110. The third wall surface 203 may include a wall surface in a transverse direction facing the first wall surface 201. That is, the third wall surface 203 may include a top surface of the cooling channel 10. The third wall surface 203 may include a lower surface of the cover 130 that covers an upper portion of the cooling channel 10. The transverse direction may include a direction parallel to the upper surface of the substrate 110, and may refer to a first direction (X) and/or a third direction (Y). The fine pattern 20 (e.g., a wick pattern) configured to generate the capillary pressure may be formed on at least some of the wall surfaces of the cooling channel 10, such as the first wall surface 201, the second wall surface 202 and the third wall surface 203.

In the semiconductor apparatus 1 according to some embodiments, a first fine pattern 210 (e.g., first wick pattern) may be provided on the first wall surface 201, and a second fine pattern 220 (e.g., second wick pattern) may be provided on the second wall surface 202. The fine pattern 20 (for example, the first fine pattern 210) may also be provided on the third wall surface 203. A capillary pressure may act as a flow pressure that induces a flow of a liquid coolant LC. The first fine pattern 210 may include a wick pattern in a transverse direction provided on the first wall surface 201 (that is, the wall surface in the transverse direction of the cooling channel 10). The first fine pattern 210 may generate the capillary pressure for moving the liquid coolant LC in the transverse direction along the first wall surface 201. The second fine pattern 220 may include a wick pattern in a longitudinal direction provided on the second wall surface 202 (that is, the wall surface in the longitudinal direction of the cooling channel 10). The second fine pattern 220 may generate the capillary pressure for moving the liquid coolant LC in the longitudinal direction along the second wall surface 202. By the second fine pattern 220, the liquid coolant LC may move toward the first wall surface 201 along the second wall surface 202. Exemplary forms of the first fine pattern 210 and the second fine pattern 220 will be described later.

The cooling channel 10 may be connected to the condenser 800 and the coolant storage 810. For example, the semiconductor chip 100 may be covered or at least partially covered with a package housing 700, such that the package housing 700 may surround or at least partially surround the semiconductor chip 100. The package housing 700 may include a first opening 701 for discharging the vapor coolant VC from the cooling channel 10, and a second opening 702 for supplying the liquid coolant LC to the cooling channel 10. The first opening 701 may include an outlet through which the vapor coolant VC is discharged from the cooling channel 10. The second opening 702 may include an inlet through which the liquid coolant LC is supplied to the cooling channel 10. The first opening 701 may be connected to the condenser 800. The second opening 702 may be connected to the coolant storage 810. When the condenser 800 also serves a function of the coolant storage 810, the first opening 701 and the second opening 702 may be connected to the condenser 800.

The cooling channel 10 described above may form a cycle in which a coolant may circulate within the semiconductor apparatus 1. The cooling channel 10 may provide the cycle in which the coolant circulates to cool the semiconductor chip 100 within the semiconductor apparatus 1. The cycle provided by the cooling channel 10 may be to supply the liquid coolant LC capable of cooling the semiconductor chip 100 within the semiconductor apparatus 1. The cycle provided by the cooling channel 10 may be to recover the liquid coolant LC vaporized into the vapor coolant VC and supply the liquid coolant LC back to the semiconductor chip 100. The vaporization of the liquid coolant LC into the vapor coolant VC may include at least part of a process in which the liquid coolant LC cools the semiconductor chip 100. The vapor coolant VC may be liquefied into the liquid coolant LC in the condenser 800. In order for the cooling channel 10 to form the cycle within the semiconductor apparatus 1, the liquid coolant LC liquefied in the condenser 800 may need to be supplied back inside the semiconductor chip 100. However, the circulation of the coolant within the semiconductor apparatus 1 is not limited to the above description.

In the cooling channel 10 according to some embodiments, the vapor coolant VC may emit heat when the vapor coolant VC is liquefied in the condenser 800. The vapor coolant VC may emit the heat to the condenser 800. The condenser 800 may absorb the heat of the vapor coolant VC. The condenser 800 may have a lower temperature than the vapor coolant VC. The vapor coolant VC may have a higher temperature than the condenser 800. A temperature at which the vapor coolant VC is liquefied in the condenser 800 may include a boiling point temperature of the liquid coolant LC. The condenser 800 may have a temperature lower than the boiling point temperature of the liquid coolant LC. The temperature of the condenser 800 may include a temperature of an internal environment of the condenser 800 that exchanges heat with the vapor coolant VC. However, the temperature of the condenser 800 is not limited to the above description.

The vapor coolant VC may exchange heat with the condenser 800 and phase change into the liquid coolant LC. The vapor coolant VC may be condensed into the liquid coolant LC in the condenser 800. In a process of liquefying the vapor coolant VC into the liquid coolant LC, a subcooling phenomenon may occur. The subcooling phenomenon may be a phenomenon in which the condenser 800 decreases a temperature of the liquid coolant LC even after the vapor coolant VC is condensed into the liquid coolant LC. The subcooling phenomenon may be a phenomenon in which the liquid coolant LC emits heat to the condenser 800. The subcooling phenomenon may be a phenomenon in which the condenser 800 absorbs heat of the liquid coolant LC. In other words, the temperature of the liquid coolant LC may be decreased to be less than a boiling point temperature after the vapor coolant VC is condensed into the liquid coolant LC in the condenser 800.

The condenser 800 according to some embodiments may supply the condensed liquid coolant LC back to the cooling channel 10. The condenser 800 may supply the liquid coolant LC to the second opening 702. The liquid coolant LC supplied by the condenser 800 may include a subcooled liquid coolant LC. The subcooled liquid coolant LC may include a liquid coolant LC at a temperature less than a saturation temperature. The subcooled liquid coolant LC may include a liquid coolant LC of an unsaturated state. The subcooled liquid coolant LC may include a liquid coolant LC at a temperature less than the boiling point temperature. The temperature of the liquid coolant LC supplied by the condenser 800 may be less than the boiling point temperature. However, the temperature of the liquid coolant LC supplied by the condenser 800 is not limited to the above description.

The semiconductor apparatus 1 according to some embodiments may include a temperature controller 50. The temperature controller 50 may control a supply temperature of the liquid coolant LC supplied to the cooling channel 10. The temperature controller 50 may control the supply temperature of the liquid coolant LC such that the liquid coolant LC is supplied at a temperature of a high heat exchange efficiency. The temperature controller 50 may control the supply temperature of the liquid coolant LC such that the liquid coolant LC is supplied into the cooling channel 10 at a temperature at which a saturated boiling may occur. The temperature controller 50 may control the supply temperature of the liquid coolant LC such that the liquid coolant LC is supplied in a state in which the supply temperature of the liquid coolant LC is approximate to the boiling point temperature. The supply temperature may include a temperature of the liquid coolant LC supplied by the condenser 800 to the cooling channel 10. The supply temperature may include a temperature of the liquid coolant LC supplied to the cooling channel 10. The supply temperature may include a temperature of the liquid coolant LC that cools the semiconductor chip 100. The supply temperature may include a temperature of the liquid coolant LC that is introduced into the second opening 702. However, the supply temperature of the liquid coolant LC is not limited to the above description.

The temperature controller 50 according to some embodiments may control a supply temperature of the liquid coolant LC supplied from the inside of the coolant storage 810 to the inside of the semiconductor apparatus 1. At least a portion of the temperature controller 50 may be disposed on the coolant storage 810. The at least portion of the temperature controller 50 may be disposed on a pipe connecting the coolant storage 810 with the second opening 702 of the semiconductor apparatus 1. The at least portion of the temperature controller 50 may be disposed on a pipe connecting the coolant storage 810 with the cooling channel 10. The at least portion of the temperature controller 50 may be disposed on the second opening 702. The at least portion of the temperature controller 50 may be disposed on an upper flow path of the liquid coolant LC flowing along the cooling channel 10. The upper flow path may include a region, on a flow path of the liquid coolant LC, where the liquid coolant LC begins to absorb heat from the semiconductor apparatus 1. The upper flow path may include a region, on the flow path of the liquid coolant LC, which is close to a hot spot of the semiconductor chip 100. However, the arrangement of the temperature controller 50 is not limited to the above description.

A method of controlling the supply temperature of the liquid coolant LC by the temperature controller 50 will be described later in detail.

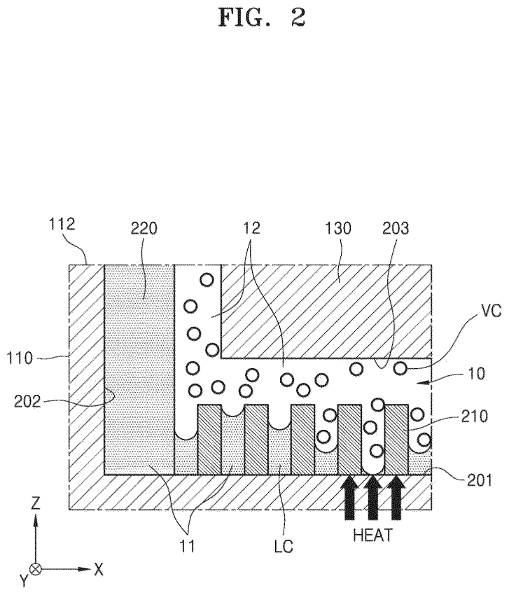

FIG. 2 is a diagram illustrating a cooling channel according to an embodiment.

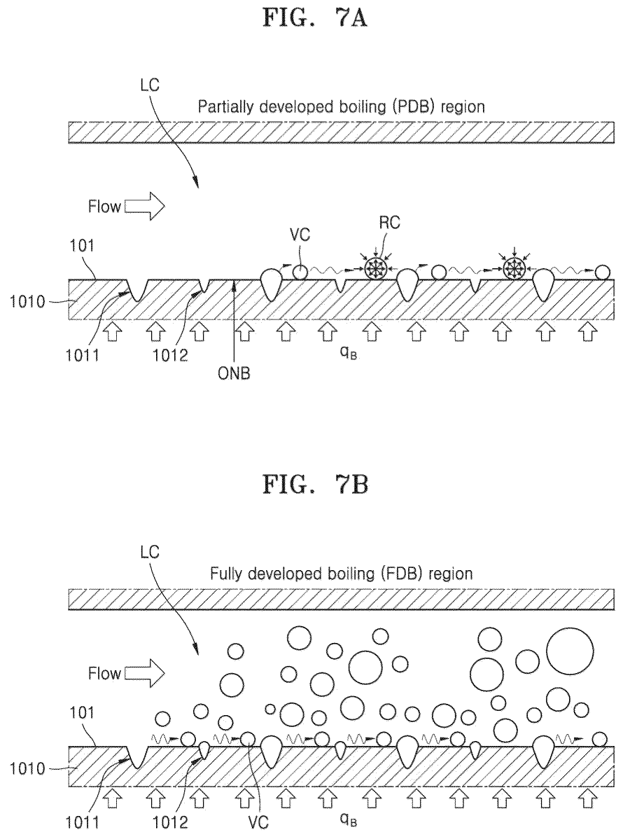

Referring to FIG. 2, the cross-sectional region of the cooling channel 10 according to some embodiments may include the liquid channel region 11 and the vapor channel region 12. The liquid channel region 11 may be a region where the first fine pattern 210 and the second fine pattern 220 are formed. The liquid channel region 11 may include a transverse region in which the first fine pattern 210 is formed along the first wall surface 201 of the cooling channel 10, and a longitudinal region in which the second fine pattern 220 is formed along the second wall surface 202 of the cooling channel 10. The first fine pattern 210 and the second fine pattern 220 may generate the capillary pressure such that the liquid coolant LC is filled in the liquid channel region 11. The liquid channel region 11 may form a passage for the liquid coolant LC. The capillary pressure may be generated by forming the second fine pattern 220 on the second wall surface 202 that is a longitudinal wall surface of the cooling channel 10. By the capillary pressure, the liquid coolant LC introduced into the package housing 700 through the second opening 702 of the package housing 700 may be supplied into the cooling channel 10 along the second wall surface 202. The liquid coolant LC may move along the first wall surface 201 by the capillary pressure generated by the first fine pattern 210. The first wall surface 201 may include a wall surface that is closest to the semiconductor integrated circuit 120 among the wall surfaces of the cooling channel 10. The first wall surface 201 may include the heat transfer surface 101 of FIGS. 7A and 7B through which heat is transferred from the semiconductor integrated circuit 120 to the liquid coolant LC of the cooling channel 10. In this way, the liquid channel region 11 may be formed to include the first wall surface 201 close to the semiconductor integrated circuit 120 among the wall surfaces of the cooling channel 10, whereby heat generated by the semiconductor integrated circuit may be effectively transferred to the liquid coolant LC through the first wall surface 201. Also, by the first fine pattern 210, a surface area of the first wall surface 201, which is the heat transfer surface 101 of FIGS. 7A and 7B, may be increased and thus a heat exchange efficiency between the semiconductor integrated circuit 120 and the liquid coolant LC may be increased. Heat generated from the heat source (that is, the semiconductor integrated circuit 120) may be transferred to, for example, the liquid coolant LC within the liquid channel region 11. The liquid coolant LC may be vaporized in the liquid channel region 11 and be phase changed into the vapor coolant VC.

The vapor channel region 12 may include a region in which the first fine pattern 210 and the second fine pattern 220 are not formed, among internal regions of the cooling channel 10. That is, the vapor channel region 12 may include a remaining region excluding the liquid channel region 11 among the internal regions of the cooling channel 10. The vapor channel region 12 may communicate with the liquid channel region 11.

Referring to FIGS. 1 and 2, in the cooling channel 10 according to some embodiments, the vapor channel region 12 may include a region extending in a transverse direction between the third wall surface 203 of the cooling channel 10 and a longitudinal end of the first fine pattern 210 formed on the first wall surface 201, and a region extending in a longitudinal direction between the third wall surface 203 and a transverse end of the second fine pattern 220 formed on the second wall surface 202. The vapor channel region 12 may form a passage for the vapor coolant VC. The vapor coolant VC generated in the liquid channel region 11 may move to the vapor channel region 12. An empty space, from which the vapor coolant VC has escaped, of the liquid channel region 11 may be continuously filled with the liquid coolant LC. The vapor coolant VC may move to the condenser 800 through the first opening 701 of the package housing 700 along the vapor channel region 12. The vapor coolant VC may be phase changed into the liquid coolant LC in the condenser 800 and then be accommodated in the coolant storage 810. The liquid coolant LC may be again supplied into the package housing 700 through the second opening 702 provided in the package housing 700, and be moved along the liquid channel region 11 of the cooling channel 10 by the capillary pressure.

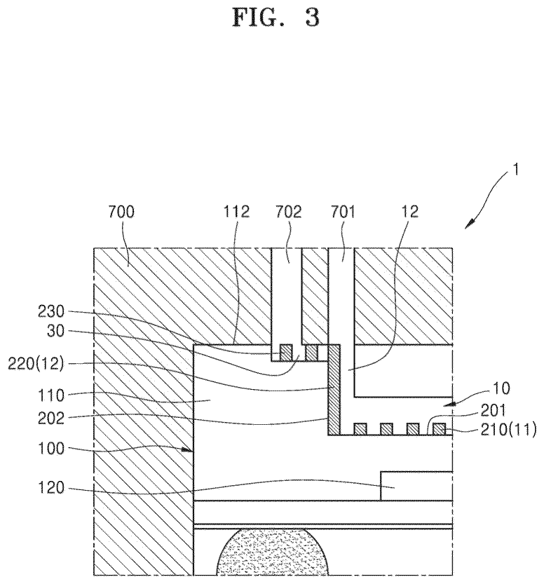

FIG. 3 is a diagram illustrating a semiconductor apparatus according to an embodiment.

FIG. 3 illustrates only portions different from those according to some embodiments of the semiconductor apparatus 1 shown in FIG. 1, and the description of the semiconductor apparatus 1 shown in FIG. 1 is applied to the embodiment of the semiconductor apparatus 1 shown in FIG. 3. Therefore, the same components are indicated by the same reference numerals and an overlapping description may be omitted.

Referring to FIGS. 1 to 3, the semiconductor apparatus 1 according to some embodiments may include a supply channel 30. The supply channel 30 may be provided on an upper surface of the semiconductor chip 100. The supply channel 30 may connect the second opening 702 with the cooling channel 10. The supply channel 30 may be provided between the package housing 700 and the upper surface 112 of the semiconductor chip 100 (for example, an upper surface 112 of the substrate 110). By the supply channel 30, the second opening 702 may be connected with the liquid channel region 11 of the cooling channel 10. The supply channel 30 may be provided with a third fine pattern 230 for generating a capillary pressure for moving the liquid coolant LC. The third fine pattern 230 may form the capillary pressure. The third fine pattern 230 may generate the capillary pressure for moving, to the cooling channel 10, the liquid coolant LC introduced through the second opening 702. For example, the third fine pattern 230 may be provided on the upper surface 112 of the semiconductor chip 100 (for example, the upper surface 112 of the substrate 110). By this, the liquid coolant LC introduced from the coolant storage 810 through the second opening 702 may move along the supply channel 30 by the capillary pressure and be effectively supplied to the liquid channel region 11 of the cooling channel 10. The third fine pattern 230 may be the same as or different from the first fine pattern 210. The supply channel 30 may be formed in a region, which is connected to at least a portion of the cooling channel 10, of the upper surface 112 of the semiconductor chip 100 (that is, the upper surface 112 of the substrate 110). The supply channel 30 may be formed in a region, which surrounds the cooling channel 10, of the upper surface 112 of the semiconductor chip 100 (that is, the upper surface 112 of the substrate 110). The supply channel 30 may be formed on the entirety of the upper surface 112 of the semiconductor chip 100 (that is, the upper surface 112 of the substrate 110).

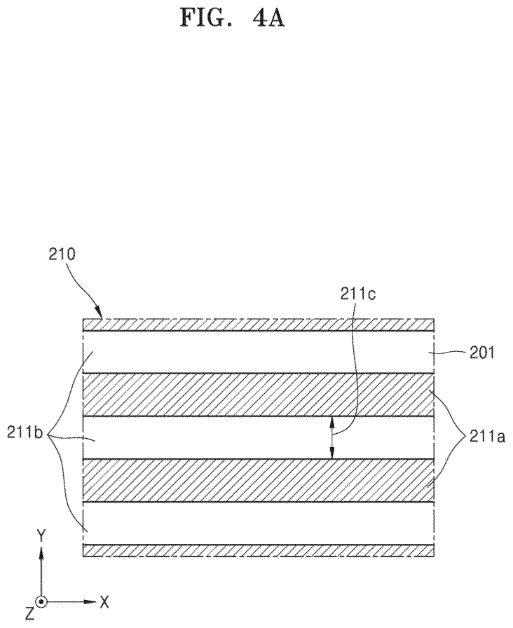

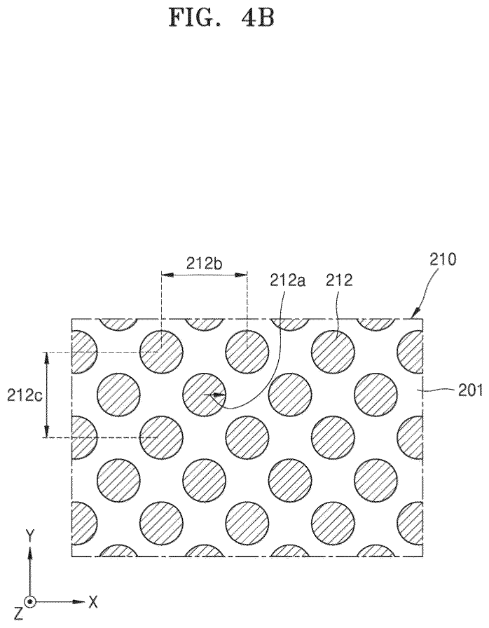

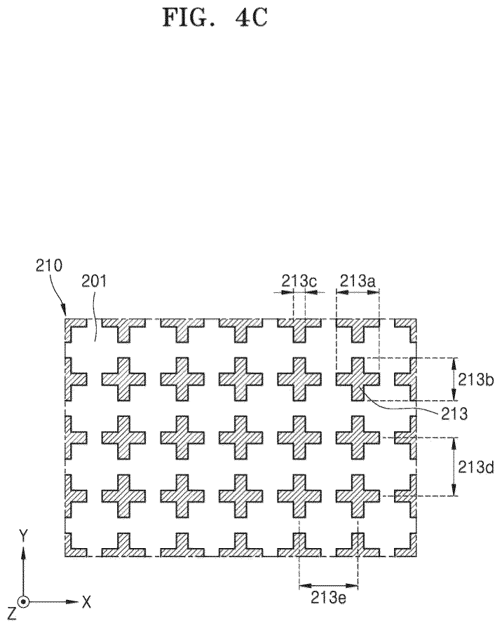

FIGS. 4A to 4C are plan views illustrating a fine pattern according to an embodiment.

Referring to FIGS. 1 to 4C, the first fine pattern 210 may include a plurality of ridges 211a extending in a transverse direction (for example, in a first direction (X)). The plurality of ridges 211a may protrude from the first wall surface 201 of the cooling channel 10 (for example, in a third direction (Z)). The plurality of ridges 211a may be arranged to be spaced apart from each other at intervals 211c in a second direction (Y), and form a wick. A plurality of grooves 211b may be formed between the plurality of ridges 211a, and a liquid coolant LC may move along the plurality of grooves 211b by a capillary phenomenon. The interval 211c between the plurality of grooves 211b, the width of the grooves 211b, and the height of the grooves 211b may be determined to generate a capillary pressure.

Referring to FIGS. 4B and 4C, the first fine pattern 210 may include a plurality of fine protrusions 212 or 213 arranged in two dimensions in a transverse direction (that is, a first direction (X) and a second direction (Y)). The plurality of fine protrusions 212 or 213 may protrude in a third direction (Z) from the first wall surface 201 of the cooling channel 10.

A cross-sectional shape in a transverse direction of the fine protrusion 212 shown in FIG. 4B may include a circular shape. The liquid coolant LC may move into a space between two adjacent fine protrusions 212 by the capillary phenomenon. As shown in FIG. 4B, each fine protrusion may have a radius 212a. The centers of the fine protrusions 212 arranged parallelly in the X-direction may be separated by a distance 212b, and the centers of the fine protrusions 212 arranged parallelly in the Y-direction may be separated by a distance 212c, which may be substantially equal to distance 212b.

A cross-sectional shape in a transverse direction of the fine protrusion 213 shown in FIG. 4C may include a cross shape. The liquid coolant LC may move into a space between two adjacent fine protrusions 213 by the capillary phenomenon. Each cross shape may have an overall width 213a and an overall height 213b that is substantially equal to the overall width 213a. Each cross shape may have a central width 213c. The centers of the cross shapes may be horizontally spaced by distance 213e, and vertically spaced by vertical distance 213d, which may be substantially equal to distance 213e.

Various examples of the first fine pattern 210 shown in FIGS. 4A to 4C are exemplary and may have various cross-sectional shapes and arrangements capable of forming the capillary pressure for moving the liquid coolant LC. For example, in FIG. 4A, a cross-sectional shape in a longitudinal direction of the ridge 211a may include any shape capable of generating the capillary pressure, such as various polygonal shapes such as a triangle and a square, a partially circular shape, and a partially elliptical shape. Also, the cross-sectional shape in the longitudinal direction of the ridge 211a do not all need to be the same, and a first capillary structure may be also implemented by ridges 211a having two or more different cross-sectional shapes in the longitudinal direction. In FIGS. 4B and 4C, the shape of the fine protrusion 212 or 213 may include any polygonal or irregular shape. Also, the cross-sectional shape in the longitudinal direction of the fine protrusion 212 or 213 do not all need to be the same, and a first capillary structure may be also implemented by fine protrusions 212 or 213 having two or more different cross-sectional shapes in the longitudinal direction.

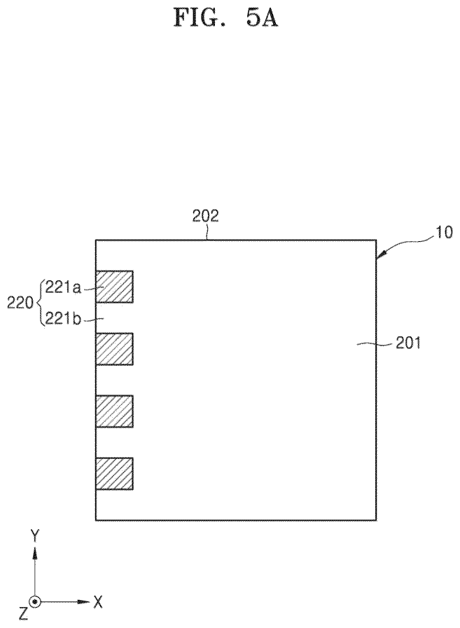

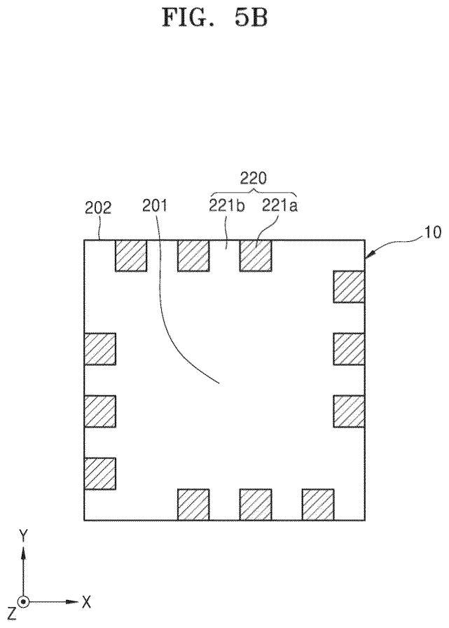

FIGS. 5A and 5B are plan views illustrating a cooling channel and a fine pattern according to an embodiment.

For convenience of description, in FIGS. 5A and 5B, the first fine pattern 210 provided on the first wall surface 201 is omitted, and the size of the second fine pattern 220 is exaggerated. Referring to FIGS. 3, 5A, and 5B, a cross-sectional shape in a transverse direction of the cooling channel 10 may include a square. However, the cross-sectional shape of the cooling channel 10 may include a shape such as a triangle or a circle in addition to the square.

The second fine pattern 220 according to some embodiments may include a plurality of ridges 221a. In FIG. 5A, the plurality of ridges 221a may extend in a transverse direction from four second wall surfaces 202 of the cooling channel 10. The plurality of ridges 221a may be arranged to be spaced apart from each other at intervals in a second direction (Y). In FIG. 5B, the plurality of ridges 221a may extend in a transverse direction from the four second wall surfaces 202 of the cooling channel 10 to the inside of the cooling channel 10. The plurality of ridges 221a may be arranged to be spaced apart from each other in a first direction (X) or the second direction (Y). A plurality of grooves 221b may be formed between the plurality of ridges 221a. The liquid coolant LC may move along the cooling channel 10 by a capillary phenomenon occurring along the plurality of grooves 221b.

When the supply channel 30 is provided as shown in FIG. 3, the supply channel 30 may be formed to wholly or partially surround the cooling channel 10. The shape of the third fine pattern 230 may include a form shown in FIGS. 4A to 4C. However, the third fine pattern 230 is not limited to the examples shown in FIGS. 4A to 4C, and may have various cross-sectional shapes and arrays capable of forming the capillary pressure for moving the liquid coolant LC along the supply channel 30.

Only one cooling channel 10 is illustrated in FIGS. 1 to 3, but the number of cooling channels 10 may be two or more. The plurality of cooling channels 10 may be arranged in the transverse direction (for example, the first direction (X) and/or the second direction (Y)). The package housing 700 may include a plurality of first openings 701 corresponding to the plurality of cooling channels 10 respectively. At least one second opening 702 may be provided. A plurality of second openings 702 corresponding to the plurality of cooling channels 10 respectively may be provided. The supply channel 30 including the third fine pattern 230 may be also provided between the plurality of cooling channels 10 and the plurality of second openings 702. The supply channel 30 may be formed to partially or wholly surround the plurality of cooling channels 10, and at least one second opening 702 may be connected to the supply channel 30 as well. The third fine pattern 230 may be formed in the supply channel 30.

The cooling channel 10 may be provided inside the semiconductor chip 100, for example, the substrate 110, and be partially open to an upper surface 112 of the substrate 110. That is, an upper portion of the cooling channel 10 may be covered with the cover 130. A lower surface of the cover 130 may form the third wall surface 203 of the cooling channel 10. However, a structure of the cooling channel 10 is not limited thereto. The cooling channel 10 may be wholly open to an upper surface 112 of the semiconductor chip 100 (for example, the upper surface 112 of the substrate 110).

The temperature controller 50 of the semiconductor apparatus 1 will be described below in detail. Description overlapping with the above description may be omitted.

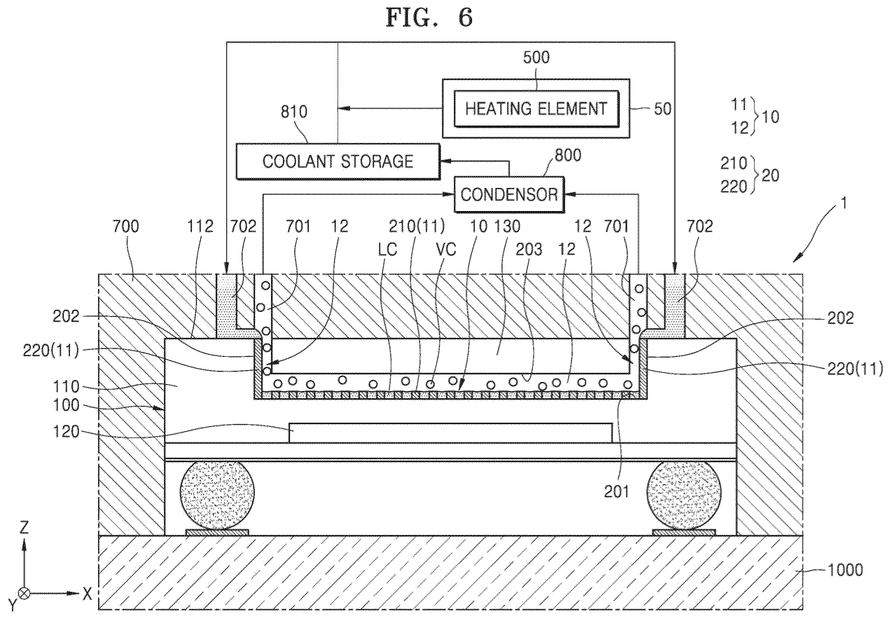

FIG. 6 is a diagram illustrating a semiconductor apparatus according to an embodiment.

Referring to FIG. 6, a temperature controller 50 of the semiconductor apparatus 1 according to some embodiments may include a heating element 500. The heating element 500 may control a supply temperature of a liquid coolant LC supplied to a cooling channel 10. The liquid coolant LC supplied to the cooling channel 10 may include a liquid coolant LC supplied to the cooling channel 10 through a second opening 702 of the semiconductor apparatus 1. The liquid coolant LC supplied to the cooling channel 10 may include a liquid coolant LC supplied to cool the semiconductor chip 100.

The heating element 500 may be configured to preheat the liquid coolant LC. The heating element 500 may heat the liquid coolant LC supplied to the cooling channel 10. The heating element 500 may prevent the liquid coolant LC supplied to the cooling channel 10 from being supplied in a subcooled state. The subcooled state may include a state when a temperature of the liquid coolant LC is less than a boiling point temperature. The subcooled state may include a state when the liquid coolant LC is in an unsaturated state. The heating element 500 may prevent the liquid coolant LC supplied to the cooling channel 10 from being supplied in the unsaturated state. The heating element 500 may heat the liquid coolant LC such that the temperature of the liquid coolant LC supplied to the cooling channel 10 is approximate to the boiling point temperature. However, when the heating element 500 heats the liquid coolant LC, the liquid coolant LC may not always reach the boiling point temperature. For example, the heating element 500 may heat the liquid coolant LC such that the liquid coolant LC of the unsaturated state may be approximate to the boiling point temperature.

When the liquid coolant LC supplied to the cooling channel 10 is supplied at a temperature approximate to the boiling point temperature, a heat transfer efficiency of the semiconductor apparatus 1 may be high. The temperature and heat transfer efficiency of the liquid coolant LC supplied to the cooling channel 10 will be described below.

FIG. 7A is a diagram illustrating heat transfer by partial boiling of a liquid coolant supplied in an unsaturated state according to an embodiment. FIG. 7B is a diagram illustrating heat transfer by saturated boiling of a liquid coolant supplied in a saturated state according to an embodiment.

In FIGS. 7A and 7B, the liquid coolant LC may flow to the right within a flat plate 1010. A uniform heat transfer q_{B} may occur from a lower portion of the flat plate 1010 toward the liquid coolant LC. The liquid coolant LC may absorb heat from the flat plate 1010 while flowing to the right. The flat plate 1010 may include a first groove 1011 and a second groove 1012 smaller than the first groove 1011. An area where the liquid coolant LC may receive heat from the flat plate 1010 may be larger in the first groove 1011 than in the second groove 1012. The liquid coolant LC may better perform heat transfer in the first groove 1011 than in the second groove 1012.

The liquid coolant LC supplied in the unsaturated state partially boils (partially developed boiling (PDB)) while flowing within the flat plate 1010. Referring to FIG. 7A, the liquid coolant LC supplied in the unsaturated state is not converted into a vapor coolant VC before reaching an onset of nucleate boiling (ONB). The ONB may include a time point at which the vapor coolant VC begins to be condensed while being formed. The ONB may include a time point at which the liquid coolant LC reaches a boiling point. The liquid coolant LC supplied in the unsaturated state may not phase change into the vapor coolant VC before the ONB, in spite of the heat transfer q_{B} of the flat plate. Before the ONB, a temperature of the liquid coolant LC supplied in the unsaturated state may increase until the liquid coolant LC reaches the boiling point. In other words, before the ONB, the liquid coolant LC may absorb heat of the flat plate through a specific heat change not a latent heat change.

Also, the temperature of the liquid coolant LC may not be uniform wholly. Therefore, even after the ONB, the temperature of the liquid coolant LC that is away from the heat transfer surface 101 may be maintained in the unsaturated state. Therefore, even after the liquid coolant LC is phase changed into the vapor coolant VC, the recondensation RC of the vapor coolant VC may occur. The recondensation RC may include that the vapor coolant VC emits heat to the surrounding liquid coolant LC and is again phase changed into the liquid coolant LC.

In contrast, referring to FIG. 7B, the liquid coolant LC supplied at a saturation temperature may undergo a saturated boiling (fully developed boiling (FDB)) while flowing within the flat plate 1010. Since a temperature of the liquid coolant LC flowing within the flat plate 1010 is wholly uniform as the saturation temperature, the vapor coolant VC may not be recondensed into the liquid coolant LC. The liquid coolant LC supplied at the saturation temperature may directly undergo a latent heat change into the vapor coolant VC, without undergoing a specific heat change, through heat transfer supplied from the flat plate 1010. Also, the liquid coolant LC may be phase changed into the vapor coolant VC not only in the first groove 1011 but also in the second groove 1012. Therefore, a rate of phase changing the liquid coolant LC into the vapor coolant VC when the liquid coolant LC of the saturation temperature is supplied as shown in FIG. 7B may be higher than that of when the liquid coolant LC of the unsaturated state is supplied as shown in FIG. 7A.

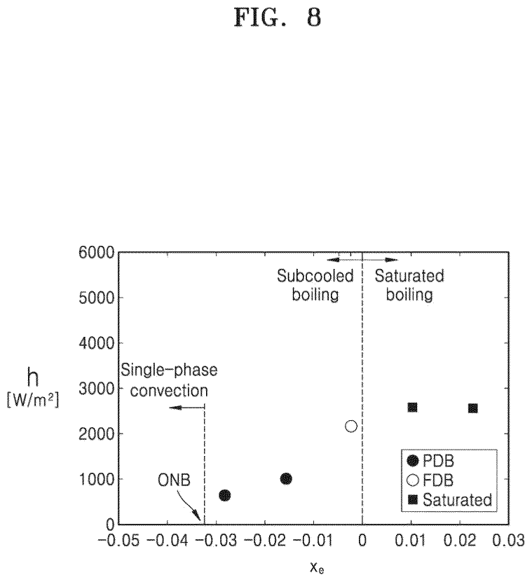

FIG. 8 is a graph illustrating a heat exchange efficiency of a liquid coolant that exchanges heat in an unsaturated state and a saturated state according to an embodiment. In the graph of FIG. 8, a horizontal axis indicates a degree of saturation Xₑ. The degree of saturation Xₑ has a relationship between a supply temperature T_{f} and a saturation temperature Tₛₐₜ as shown in Equation (1) below.

$${X}_{e} = \frac{{T}_{f} - {T}_{sat}}{{T}_{sat}} \qquad ( 1 )$$

The saturation temperature Tₛₐₜ of the liquid coolant LC may include a boiling point temperature of the liquid coolant LC.

In the graph of FIG. 8, a vertical axis indicates a heat transfer rate h. The heat transfer rate h is an amount of heat (W) absorbed by the liquid coolant LC per unit area (m²).

Referring to FIGS. 7A to 8, it may be seen that a heat transfer rate h of the liquid coolant LC supplied in the saturated state is higher than that of the liquid coolant LC supplied in the unsaturated state. In other words, the liquid coolant LC supplied in the saturated state may better absorb heat from the flat plate 1010 than the liquid coolant LC flowing in the unsaturated state within the flat plate 1010.

The saturated state referred to here may include a state wherein the liquid coolant LC is supplied at a boiling point temperature. However, that the liquid coolant LC is in the saturated state does not mean only that the liquid coolant LC is exactly at the boiling point temperature. As seen from the graph of FIG. 8, the liquid coolant LC supplied in the unsaturated state is supplied in a relatively saturated state as the liquid coolant LC approaches to the boiling point temperature.

Referring to FIGS. 6 to 8, when the semiconductor apparatus 1 according to some embodiments supplies the liquid coolant LC to the cooling channel 10 in the saturated state, a heat transfer efficiency of the cooling channel 10 may be increased. The temperature controller 50 may heat the liquid coolant LC supplied to the cooling channel 10 and increase the heat transfer efficiency of the semiconductor apparatus 1. The heating element 500 may heat the liquid coolant LC supplied to the cooling channel 10 and increase the heat transfer efficiency of the semiconductor apparatus 1. The heating element 500 may heat the liquid coolant LC supplied to the cooling channel 10 to the saturation temperature and increase the heat transfer efficiency of the semiconductor apparatus 1. The heating element 500 may heat the liquid coolant LC supplied to the cooling channel 10 up to the boiling point temperature, and increase the heat transfer efficiency of the semiconductor apparatus 1. However, as described above, heating the liquid coolant LC by the heating element 500 may refer to heating the liquid coolant LC such that the liquid coolant LC is supplied to the cooling channel 10 at a temperature approximate to the boiling point temperature.

The temperature controller 50 according to some embodiments may heat the liquid coolant LC supplied to the cooling channel 10. The heating element 500 may heat the liquid coolant LC supplied to the cooling channel 10. The heating element 500 may prevent the liquid coolant LC supplied to the cooling channel 10 from being supplied in an unsaturated state. The unsaturated state may include a state wherein a temperature of the liquid coolant LC is less than a boiling point temperature. The heating element 500 may heat the liquid coolant LC supplied to the cooling channel 10 such that the temperature of the liquid coolant LC reaches the boiling point temperature. However, as described above, heating the liquid coolant LC by the heating element 500 may indicate heating the liquid coolant LC such that the liquid coolant LC is supplied to the cooling channel 10 at the temperature approximate to the boiling point temperature.

The temperature controller 50 according to some embodiments may preheat the liquid coolant LC supplied to the cooling channel 10 such that the liquid coolant LC supplied to the cooling channel 10 is supplied at a temperature capable of phase changing into a vapor coolant VC. The heating element 500 may preheat the liquid coolant LC supplied to the cooling channel 10 such that the liquid coolant LC supplied to the cooling channel 10 is supplied at the temperature capable of phase changing into the vapor coolant VC. The temperature of phase changing the liquid coolant LC into the vapor coolant VC may include a temperature at which the liquid coolant LC may undergo a saturated boiling in the cooling channel 10. However, the temperature of phase changing the liquid coolant LC into the vapor coolant VC may include a boiling point temperature of the liquid coolant LC. However, the temperature of phase changing the liquid coolant LC into the vapor coolant VC is not limited to the above description.

The temperature controller 50 may control a temperature of the liquid coolant LC supplied to the cooling channel 10 according to the temperature of the liquid coolant LC supplied to the cooling channel 10. The temperature controller 50 may control the temperature of the liquid coolant LC supplied to the cooling channel 10 according to the degree of saturation of the liquid coolant LC supplied to the cooling channel 10.

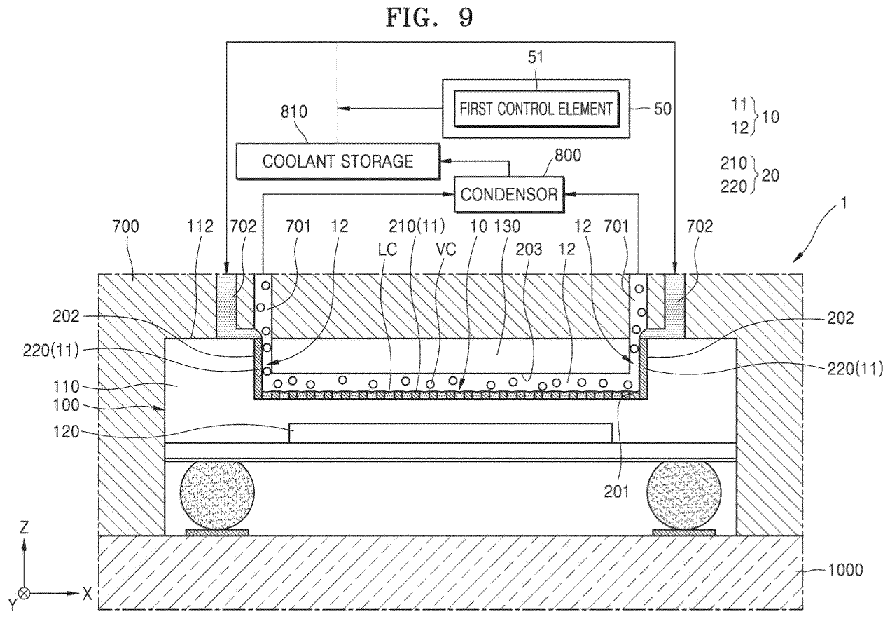

FIG. 9 is a diagram illustrating a semiconductor apparatus according to an embodiment.

Referring to FIG. 9, a temperature controller 50 according to some embodiments may include a first control element 51. The first control element 51 may be configured to detect a temperature of a liquid coolant LC supplied to a cooling channel 10. The first control element 51 may detect a degree of saturation of the liquid coolant LC supplied to the cooling channel 10. The saturation degree may include a value obtained by dividing, by a boiling point temperature of the liquid coolant LC, a value obtained by subtracting the boiling point temperature from the temperature of the liquid coolant LC supplied to the cooling channel 10. However, a method of deriving the saturation degree is not limited to the above description. For example, when the saturation degree is determined, a certain value may be added, subtracted, or multiplied according to the characteristics of the liquid coolant LC and the cooling channel 10.

When the saturation degree, which is detected by the first control element 51, of the liquid coolant LC supplied to the cooling channel 10 is low, the temperature controller 50 may heat the liquid coolant LC supplied to the cooling channel 10. When the saturation degree of the liquid coolant LC is low, the temperature of the liquid coolant LC supplied to the cooling channel 10 may be relatively lower than the boiling point temperature of the liquid coolant LC.

When the saturation degree, which is detected by the first control element 51, of the liquid coolant LC supplied to the cooling channel 10 is high (that is, when the liquid coolant LC is supplied to the cooling channel 10 in a saturated state), the temperature controller 50 may not heat the liquid coolant LC supplied to the cooling channel 10. When the saturation degree of the liquid coolant LC is low, a saturation degree value of the liquid coolant LC may be small or be approximate to 0. When the saturation degree of the liquid coolant LC is low, the liquid coolant LC supplied to the cooling channel 10 is supplied at a boiling point temperature or a temperature approximate to the boiling point temperature.

As described above, the first control element 51 may selectively preheat the liquid coolant LC supplied to the cooling channel 10 depending on the saturation degree of the liquid coolant LC. However, the function of the first control element 51 is not limited to the above description.

The first control element 51 according to some embodiments may be arranged inside the semiconductor apparatus 1. The first control element 51 may be disposed on the cooling channel 10. The first control element 51 may be arranged within the condenser 800. The first control element 51 may be disposed on the semiconductor chip 100. However, the arrangement of the first control element 51 is not limited to the above description.

The first control element 51 may perform a function of controlling an excessive preheating of the liquid coolant LC. The first control element 51 may prevent the liquid coolant LC from being excessively heated.

Referring to FIGS. 6 to 9, when the heating element 500 excessively heats the liquid coolant LC, the liquid coolant LC may phase change into a vapor coolant VC before reaching the cooling channel 10. When the liquid coolant LC is excessively heated, a heat exchange efficiency of the semiconductor apparatus 1 may rather decrease.

Generally, when the liquid coolant LC at a temperature less than the boiling point temperature absorbs heat, the liquid coolant LC may undergo a specific heat change up to the boiling point temperature and then phase change into the vapor coolant VC by additional latent heat absorption.

The first control element 51 according to some embodiments may induce only the specific heat change of the liquid coolant LC until the liquid coolant LC does not undergo a latent heat change. In other words, the first control element 51 may preheat the liquid coolant LC until the liquid coolant LC boils into the vapor coolant VC. The first control element 51 may stop preheating the liquid coolant LC when the temperature of the liquid coolant LC reaches the boiling point temperature. The first control element 51 may preheat the liquid coolant LC until the temperature of the liquid coolant LC reaches the boiling point temperature. In some embodiments, the first control element 51 that preheats the liquid coolant LC may include the heating element 500 that heats the liquid coolant LC.

However, when the heating element 500 heats the liquid coolant LC, the liquid coolant LC may not always reach the boiling point temperature. For example, the heating element 500 may heat the liquid coolant LC such that the liquid coolant LC of an unsaturated state may approach the boiling point temperature.

The first control element 51 according to some embodiments may set a predefined temperature of the liquid coolant LC. The first control element 51 may preheat the liquid coolant LC only when the temperature of the liquid coolant LC is less than or equal to the predefined temperature. The predefined temperature may include a temperature lower than the boiling point temperature of the liquid coolant LC. The predefined temperature may include a temperature lower by a certain temperature than the boiling point temperature of the liquid coolant LC. The certain temperature may include a margin capable of preventing an excessive preheating of the liquid coolant LC. In other words, by preheating the liquid coolant LC until the liquid coolant LC reaches the predefined temperature, the first control element 51 may prevent the liquid coolant LC from being phase changed into the vapor coolant VC before the liquid coolant LC is supplied to the cooling channel 10.

However, a method of preventing the excessive preheating of the liquid coolant LC by the first control element 51 is not limited to the above description. For example, the first control element 51 may detect a pressure when preheating the liquid coolant LC and may stop preheating the liquid coolant LC when the pressure is greater than or equal to a certain pressure. For example, the first control element 51 may preheat the liquid coolant LC until the temperature of the liquid coolant LC reaches the boiling point temperature, but may stop preheating when the pressure of the liquid coolant LC is greater than or equal to the certain pressure.

The first control element 51 may be one body with the heating element 500. An embodiment of forming the first control element 51 and the heating element 500 as one body will be described below. However, the construction of the first control element 51 and the heating element 500 is not limited to this. In other words, the first control element 51 and the heating element 500 may be separate constructions.

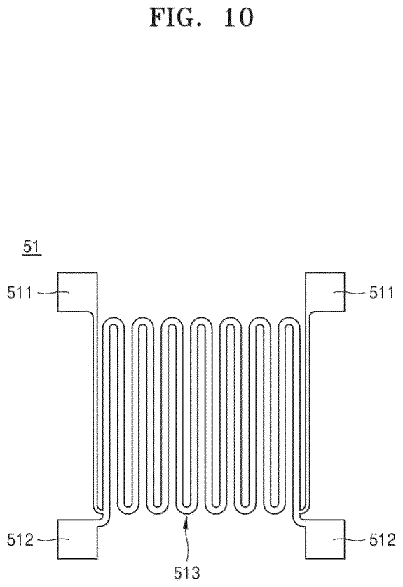

FIG. 10 is a diagram illustrating a control element according to an embodiment.

Referring to FIG. 10, the first control element 51 according to some embodiments may include a resistance temperature detector. The resistance temperature detector may be configured to perform a detection method of detecting a resistance change dependent on a temperature change. The first control element 51 may be configured to detect a sheet resistance. The first control element 51 may include a resistance temperature detector element including a thin film. The first control element 51 may detect a temperature of a liquid coolant LC supplied to a cooling channel 10 through a four-point resistance detection method. When the first control element 51 detects the temperature of the liquid coolant LC by using the four-point resistance detection method, a contact resistance may be minimized. When the first control element 51 detects the temperature of the liquid coolant LC by using the four-point resistance detection method, a temperature detection accuracy may be high.

The first control element 51 according to some embodiments may include a first detector 511, a second detector 512, and a resistor 513. The resistor 513 may be disposed on a flow path through which a liquid coolant LC flows. The resistor 513 may be disposed on the cooling channel 10. The resistor 513 may include a variable resistance material whose resistance value varies depending on temperature. A temperature of the resistor 513 may be the same as the temperature of the liquid coolant LC. The resistance value of the resistor 513 may vary depending on the temperature of the liquid coolant LC. The first detector 511 and the second detector 512 may detect the resistance value of the resistor 513. A constant current may be applied to the resistor 513 through one of the first detector 511 and the second detector 512, and a voltage applied to the resistor 513 may be detected through the other one. However, the aforementioned operation of the first control element 51 is only an exemplary description and is not limited thereto.

When the first control element 51 is the resistance temperature detector element, the first control element 51 may be used as a heating element 500. The first control element 51 may be one body with the heating element 500. The first control element 51 may simultaneously perform a function of detecting a temperature of the liquid coolant LC supplied to the cooling channel 10 and a function of preheating the liquid coolant LC supplied to the cooling channel 10. For example, the first control element 51 may preheat the liquid coolant LC by applying a current to the resistor 513 through the first detector 511 and/or the second detector 512. When the first control element 51 and the heating element 500 are formed as one body, a degree of integration of the semiconductor apparatus 1 may be high. However, the type and function of the first control element 51 and the execution or non-execution of the function of preheating the coolant are not limited to the above description.

The temperature controller 50 may control the temperature of the liquid coolant LC supplied to the cooling channel 10 according to a thermal load of the semiconductor apparatus 1. The temperature controller 50 may control the temperature of the liquid coolant LC supplied to the cooling channel 10 according to a thermal load of the semiconductor chip 100. The temperature controller 50 may control the temperature of the liquid coolant LC supplied to the cooling channel 10 according to a thermal load of the cooling channel 10.

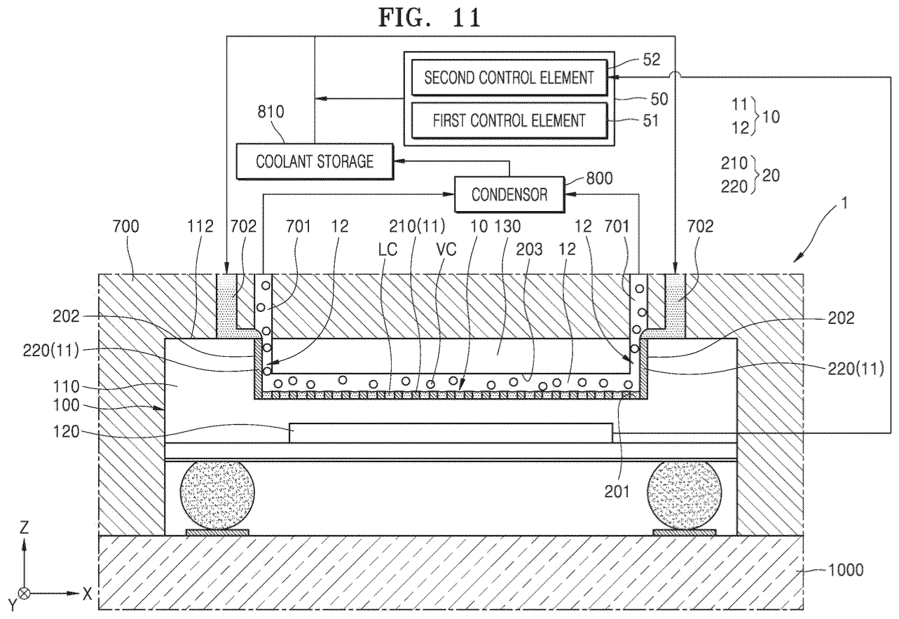

FIG. 11 is a diagram illustrating a semiconductor apparatus according to an embodiment.

Referring to FIG. 11, a temperature controller 50 according to some embodiments may include a second control element 52. The second control element 52 may be configured to detect a thermal load of a semiconductor chip 100. The second control element 52 may detect a temperature of a semiconductor integrated circuit 120. The second control element 52 may provide the temperature controller 50 with information for allowing the temperature controller 50 to determine whether to increase a heat exchange efficiency of a liquid coolant LC by preheating the liquid coolant LC. However, the function of the second control element 52 is not limited to the above description.

When the temperature of the semiconductor integrated circuit 120 detected by the second control element 52 is high, the temperature controller 50 may preheat the liquid coolant LC supplied to the cooling channel 10. When the thermal load of the semiconductor chip 100 detected by the second control element 52 is high, the temperature controller 50 may preheat the liquid coolant LC supplied to the cooling channel 10.

When the temperature of the semiconductor integrated circuit 120 detected by the second control element 52 is greater than or equal to a critical temperature, the temperature controller 50 may preheat the liquid coolant LC supplied to the cooling channel 10. The critical temperature may include a boiling point temperature of the liquid coolant LC. The critical temperature may include a saturation temperature of the liquid coolant LC. The critical temperature may include a temperature at which the liquid coolant LC may efficiently exchange heat with the semiconductor chip 100 within the cooling channel 10.

When the temperature of the semiconductor integrated circuit 120 is less than or equal to the boiling point temperature of the liquid coolant LC and the temperature controller 50 preheats the liquid coolant LC, the direction of heat transfer may be reversed. In other words, when the temperature of the liquid coolant LC supplied to the cooling channel 10 is higher than the temperature of the semiconductor integrated circuit 120 through preheating, heat may be transferred from the liquid coolant LC to the semiconductor integrated circuit 120. When (or exclusively only when in some embodiments) the temperature of the semiconductor integrated circuit 120 detected by the second control element 52 is greater than or equal to the boiling point temperature of the liquid coolant LC, the liquid coolant LC may be preheated to prevent the liquid coolant LC from transferring heat to the semiconductor chip 100. However, the method of cooling the semiconductor chip 100 by the temperature controller 50 is not limited to the above description.

When the temperature of the semiconductor chip 100 is less than the boiling point temperature of the liquid coolant LC, the temperature controller 50 may not preheat the liquid coolant LC. When the temperature of the semiconductor chip 100 is greater than or equal to the boiling point temperature of the liquid coolant LC, the temperature controller 50 may preheat the liquid coolant LC. When the temperature of the semiconductor chip 100 is greater than or equal to the boiling point temperature of the liquid coolant LC, the temperature controller 50 may preheat the liquid coolant LC until the liquid coolant LC reaches the boiling point temperature.

The second control element 52 may provide the temperature controller 50 with information for determining a need for preheating the liquid coolant LC. The temperature controller 50 may selectively determine whether to preheat the liquid coolant LC through the information provided by the second control element 52. The second control element 52 may provide an efficient temperature control of the temperature controller 50. However, the function and role of the second control element 52 are not limited to the above description.

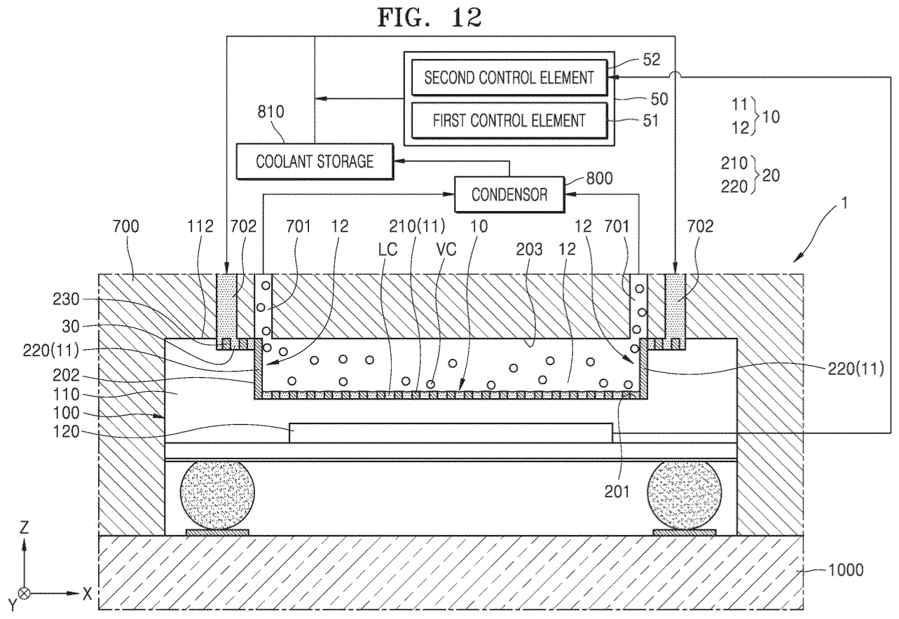

FIG. 12 is a diagram illustrating a semiconductor apparatus according to an embodiment. The embodiment of the semiconductor apparatus 1 shown in FIG. 12 is different from the embodiment of the semiconductor apparatus 1 shown in FIGS. 1 and 3, in that a cooling channel 10 is open wholly to an upper surface 112 of a semiconductor chip 100 (i.e., the cooling channel 10 extends up to the upper surface 112). Hereinafter, a component performing the same function is indicated by the same reference numeral, and overlapping descriptions are omitted.

Referring to FIG. 12, the cooling channel 10 may be formed from the upper surface 112 of the semiconductor chip 100 (for example, an upper surface 112 of a substrate 110) inward (that is, toward a semiconductor integrated circuit 120). A package housing 700 may surround or at least partially surround the semiconductor chip 100. The package housing 700 may cover or at least partially cover an upper portion of the cooling channel 10. That is, the package housing 700 may form a third wall surface 203 of the cooling channel 10. A first fine pattern 210 and a second fine pattern 220 may be formed on a first wall surface 201 and a second wall surface 202 of the cooling channel 10, respectively. By this, the cooling channel 10 that has a liquid channel region 11 and a vapor channel region 12 may be formed. A supply channel 30 may connect a second opening 702 with the cooling channel 10. A third fine pattern 230 may be provided in the supply channel 30.

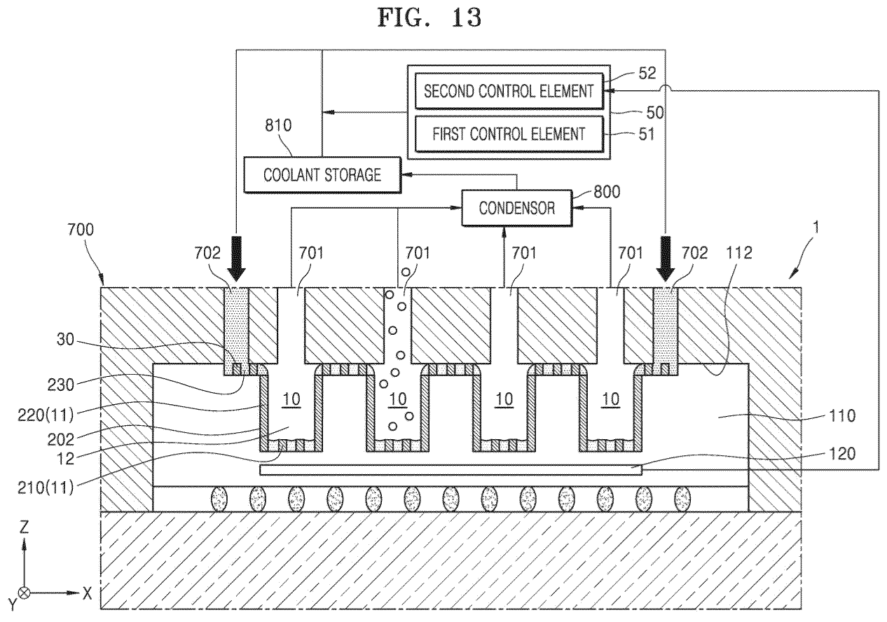

FIG. 13 is a diagram illustrating a semiconductor apparatus according to an embodiment.

Referring to FIG. 13, a plurality of cooling channels 10 may be recessed inward from an upper surface 112 of a semiconductor chip 100 *for example, an upper surface 112 of a substrate 110).

A package housing 700 may include a plurality of first openings 701 corresponding to the plurality of cooling channels 10 respectively. The plurality of first openings 701 may be connected to a condenser 800. The package housing 700 may include one or more second openings 702 connected to the plurality of cooling channels 10 through a supply channel 30. The second opening 702 may be connected to a coolant storage 810. A third fine pattern 230 may be provided in the supply channel 30. The supply channel 30 may connect all of the plurality of cooling channels 10 with the second openings 702. The supply channel 30 having the third fine pattern 230 may be formed on an upper surface 112 of the semiconductor chip 100 (for example, an upper surface 112 of the substrate 110), and at least partially surround each of the plurality of cooling channels 10. The first fine pattern 210 may be the same as the third fine pattern 230. In other words, the shape and size of unit patterns of the first fine pattern 210 may be the same as those of the third fine pattern 230, and the array intervals of the plurality of unit patterns may be the same as each other. The first fine pattern 210 and the third fine pattern 230 may be formed by a two-dimensional array in a transverse direction of square unit patterns. The shape and size of the unit patterns of the first fine pattern 210 and the third fine pattern 230 and the array intervals of the plurality of unit patterns do not necessarily need to be the same as each other. By making the first fine pattern 210 and the third fine pattern 230 the same, a manufacturing process of the semiconductor chip 100 may be simplified. For example, by etching the upper surface 112 of the substrate 110 of the semiconductor chip 100, the cooling channel 10 in a longitudinal direction (that is, a third direction (Z) from the upper surface 112 of the substrate 110) and a second fine pattern 220 protruding from a second wall surface 202 of the cooling channel 10 and extending in the longitudinal direction (that is, the third direction (Z)) may be formed.

Also, as the high integration and high performance of the semiconductor apparatus 1 progress, a plurality of semiconductor chips 100 may be stacked. The semiconductor apparatus 1 including the above-described stacked structure is also called a 3D integrated circuit. In the case of the semiconductor apparatus 1 including the stacked structure, because the plurality of semiconductor chips 100 are closely stacked, an effective two-phase liquid cooling structure is required. The semiconductor apparatus 1 of this structure may employ the two-phase liquid cooling structure described above.

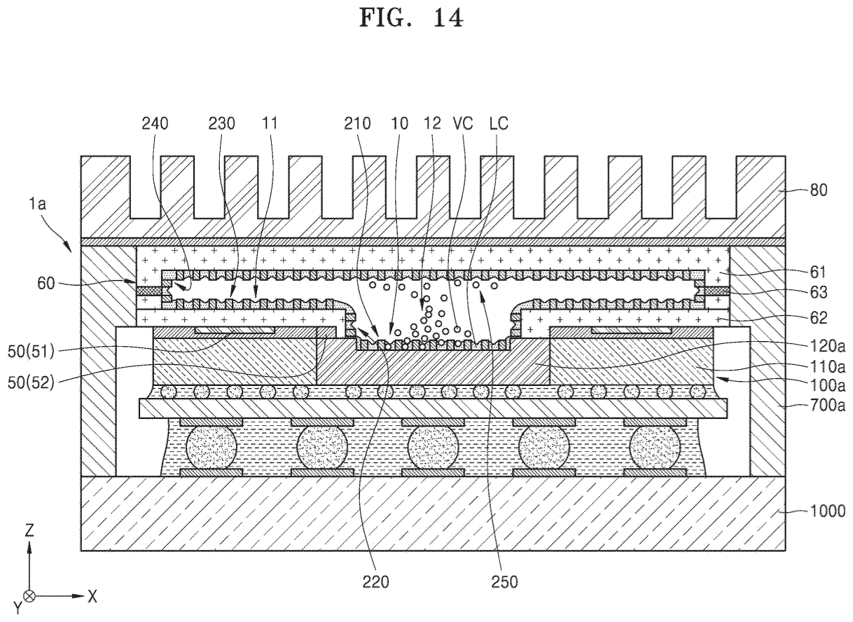

FIG. 14 is a diagram illustrating a semiconductor apparatus according to an embodiment. The embodiment of the semiconductor apparatus 1a shown in FIG. 14 is different from the embodiment of the semiconductor apparatus 1 shown in FIGS. 1, 12, and 13, in that a vapor chamber 60 is formed in a package housing 700a. Hereinafter, a component performing the same function is indicated by the same reference numeral, and overlapping descriptions may be omitted.

The semiconductor apparatus 1a according to some embodiments may further include the vapor chamber 60 disposed on a semiconductor chip 100a. A cooling channel 10 may be formed in the vapor chamber 60. At least a portion of a fine pattern 20 may be provided in the vapor chamber 60.

The cooling channel 10 according to some embodiments may be formed in the vapor chamber 60.

The vapor chamber 60 according to some embodiments may perform a role of the condenser 800 included in the semiconductor apparatus 1 shown in FIGS. 1, 12, and 13. The vapor chamber 60 may perform a role of the coolant storage 810. A liquid coolant LC and a vapor coolant VC may circulate within the semiconductor apparatus 1a. The liquid coolant LC and the vapor coolant VC may circulate within the vapor chamber 60. The vapor chamber 60 may condense the vapor coolant VC into the liquid coolant LC. However, the function of the vapor chamber 60 is not limited to the above description.

The vapor chamber 60 according to some embodiments may include an upper frame 61 and a lower frame 62. The lower frame 62 may be disposed on the semiconductor chip 100a. The upper frame 61 may be disposed on the lower frame 62. The lower frame 62 and the upper frame 61 may provide a space configured to circulate the coolant. A coolant injector 63 may be disposed in a section where the upper frame 61 is in contact with the lower frame 62. The coolant may be injected into the semiconductor apparatus 1a through the coolant injector 63.

A heat dissipater 80 may be disposed on the upper frame 61 of the vapor chamber 60 according to some embodiments. The upper frame 61 may exchange heat with the vapor coolant VC. The upper frame 61 may cool the vapor coolant VC. The upper frame 61 may condense the vapor coolant VC into the liquid coolant LC. The upper frame 61 may absorb heat of the vapor coolant VC and transfer the heat to the heat dissipater 80. However, the shape and function of the vapor chamber 60 are not limited to the above description.

The vapor chamber 60 according to some embodiments may include a fourth fine pattern 240 and a fifth fine pattern 250. The fourth fine pattern 240 and the fifth fine pattern 250 may generate a capillary pressure in the liquid coolant LC.

The upper frame 61 may include the fifth fine pattern 250. The fifth fine pattern 250 may include a region where a vapor channel region 12 formed in a longitudinal direction in the cooling channel 10 meets with the upper frame 61. The fifth fine pattern 250 may include a region where the vapor coolant VC is condensed into the liquid coolant LC. The fifth fine pattern 250 may form a movement path for the condensed liquid coolant LC. The fifth fine pattern 250 may move the liquid coolant LC in the longitudinal direction. The fifth fine pattern 250 may apply a capillary pressure such that the liquid coolant LC moves to both side ends of the vapor chamber 60.

The upper frame 61 may include the fourth fine pattern 240. The fourth fine pattern 240 may be formed at a side end of the vapor chamber 60. The fourth fine pattern 240 may apply a capillary pressure to the liquid coolant LC such that the liquid coolant LC moving through the fifth fine pattern 250 moves in the direction of the third fine pattern 230. The fourth fine pattern 240 may move the liquid coolant LC in the longitudinal direction. The fourth fine pattern 240 may move the liquid coolant LC in the direction of the third fine pattern 230. The liquid coolant LC moving through the fourth fine pattern 240 may be supplied to the third fine pattern 230. In other words, just as the liquid coolant LC is supplied to the third fine pattern 230 through the second opening 702 in FIG. 3, the liquid coolant LC may be supplied to the third fine pattern 230 through the fourth fine pattern 240. However, the functions of the fourth fine pattern 240 and the fifth fine pattern 250 are not limited to the above description.

The vapor chamber 60 according to some embodiments may expose at least a portion of the semiconductor chip 100a. The vapor chamber 60 may expose the at least portion of the semiconductor chip 100a through an opening. The lower frame 62 of the vapor chamber 60 may expose the at least portion of the semiconductor chip 100a. The semiconductor chip 100a exposed by the vapor chamber 60 may include at least a portion of a processor region 120a. The vapor chamber 60 may be sealed by the upper frame 61, the lower frame 62, and the at least portion of the semiconductor chip 100a.

The first fine pattern 210 may be formed on the at least portion of the semiconductor chip 100a exposed by the vapor chamber 60. The first fine pattern 210 may include a region where the liquid coolant LC exchanges heat with the semiconductor chip 100a. The first fine pattern 210 may include a region where the liquid coolant LC is phase changed into the vapor coolant VC.

The first fine pattern 210 may communicate with the third fine pattern 230 through the second fine pattern 220. The second fine pattern 220 may form the capillary pressure such that the liquid coolant LC may move in the longitudinal direction. The second fine pattern 220 may be formed on the vapor chamber 60. The second fine pattern 220 may be formed on the vapor chamber 60. The second fine pattern 220 may be formed on the lower frame 62 of the vapor chamber 60. However, the arrangement of the second fine pattern 220 is not limited to this. For example, the second fine pattern 220 may be also formed at a side end of the semiconductor chip 100a immersed in a down direction.

The liquid coolant LC may be phase changed into the vapor coolant VC on the first fine pattern 210 and then the vapor coolant VC may be again condensed into the liquid coolant LC on the fifth fine pattern 250 through the vapor channel region 12. The fifth fine pattern 250 may move the condensed liquid coolant LC in a lateral direction of the vapor chamber 60. The fourth fine pattern 240 may move, in the direction of the third fine pattern 230, the liquid coolant LC moving in the lateral direction of the vapor chamber 60. The third fine pattern 230 may move the liquid coolant LC in a direction where the semiconductor chip 100a is exposed. The third fine pattern 230 may move the liquid coolant LC in the direction of the opening of the vapor chamber 60. The liquid coolant LC may move in the direction of the first fine pattern 210 through the second fine pattern 220 that is formed in the longitudinal direction of the semiconductor chip 100a exposed in the direction of the vapor chamber 60. On the first fine pattern 210, the liquid coolant LC may exchange heat with the semiconductor chip 100a. However, the movement of the liquid coolant LC and vapor coolant VC within the vapor chamber 60 is not limited to the above description.

A region where the semiconductor chip 100a according to some embodiments is exposed to the inside of the vapor chamber 60 may include a region where a semiconductor integrated circuit is formed within the semiconductor chip 100a. The region where the semiconductor chip 100a is exposed to the inside of the vapor chamber 60 may include a hot spot of the semiconductor chip 100a. However, the region where the semiconductor chip 100a is exposed to the inside of the vapor chamber 60 is not limited to the above description.

The semiconductor chip 100a according to some embodiments may include a memory region 110a and the processor region 120a. The processor region 120a may include a hot spot of the semiconductor chip 100a. The processor region 120a may include a region including an integrated circuit.

At least a portion of a temperature controller 50 according to some embodiments may be disposed between the semiconductor chip 100a and the vapor chamber 60. The at least portion of the temperature controller 50 may be located between the semiconductor chip 100a and the vapor chamber 60. Specifically, the at least portion of the temperature controller 50 may be disposed between the semiconductor chip 100a and the lower frame 62 of the vapor chamber 60. The at least portion of the temperature controller 50 may be disposed between the lower frame 62 of the vapor chamber 60 and the memory region 110a. The at least portion of the temperature controller 50 may be disposed under a region where the third fine pattern 230 is formed. The at least portion of the temperature controller 50 may include a first control element 51. The at least portion of the temperature controller 50 may be disposed between the lower frame 62 of the vapor chamber 60 and the processor region 120a. The at least portion of the temperature controller 50 may be disposed under a region where the second fine pattern 220 is formed. The at least portion of the temperature controller 50 may include a second control element 52. However, the arrangement of the temperature controller 50 is not limited to the above description.

Referring to FIGS. 10 and 14, the temperature controller 50 may include the first control element 51 configured to detect a temperature of the liquid coolant LC supplied to the semiconductor chip 100a. The first control element 51 may preheat the liquid coolant LC supplied to the cooling channel 10. The first control element 51 may preheat the liquid coolant LC supplied to the first fine pattern 210. However, the functions of the temperature controller 50 and the first control element 51 are not limited to the above description.

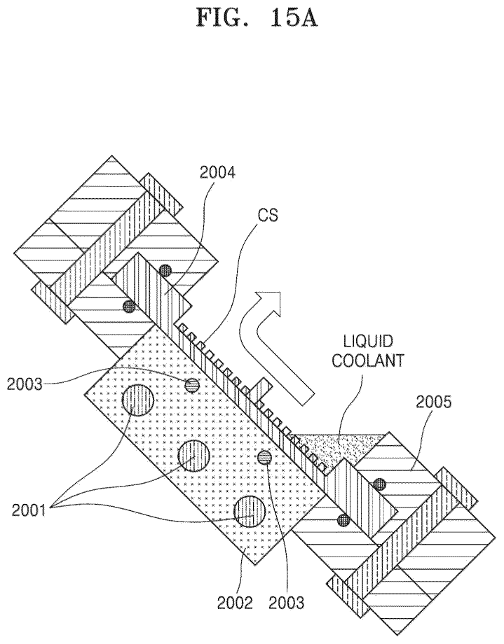

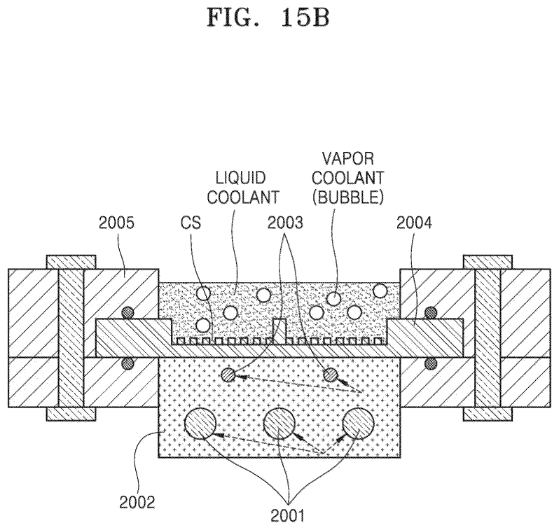

FIGS. 15A and 15B are diagrams illustrating portions a device for verifying an effect of a semiconductor apparatus according to an embodiment.

Referring to FIGS. 15A and 15B, a flat plate 2004 including a capillary structure formed on a surface of the flat plate 2004 may be disposed to contact an upper surface of a heat block 2002 including a heat source 2001. A temperature sensor 2003 may be disposed between the heat source 2001 and the flat plate 2004. As shown in FIG. 15A, this type of device may be tilted such that a liquid coolant (e.g., water) moves along the surface of the flat plate 2004 due to a capillary pressure generated by the capillary structure. In this state, the heat source 2001 may be driven and a temperature of the heat block 2002 may be detected using the temperature sensor 2003.

As shown in FIG. 15B, the device may be arranged horizontally, and the liquid coolant (e.g., water) may be filled in a container 2006 formed by the flat plate 2004 and a jig 2005, and the heat source 2001 may be driven, and a temperature of the heat block 2002 may be detected using the temperature sensor 2003.

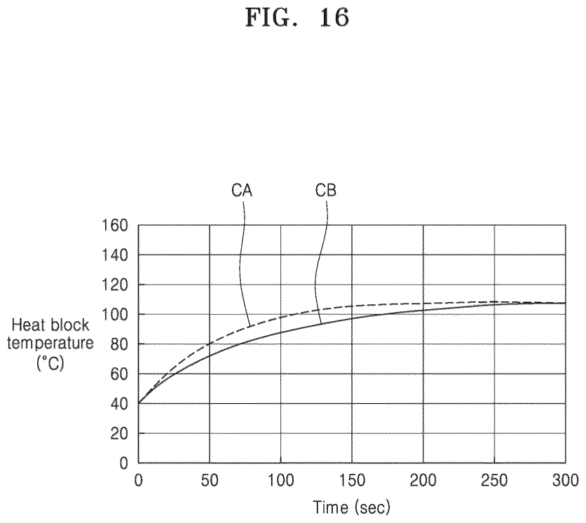

FIG. 16 is a graph illustrating results obtained by using the device of FIGS. 15A and 15B according to an embodiment. In FIG. 16, a curve CA indicates a result of an embodiment shown in FIG.>15A, and a curve CB indicates a result of an embodiment shown in FIG. 15B. Although a temperature rise time is different, a saturation temperature of the heat block 2002 of the device of FIG. 15A is the same as a saturation temperature of the heat block 2002 of the device of FIG. 15B. This may include that the semiconductor apparatus 1 of the disclosure may obtain almost the same cooling performance as that of the immersion cooling method.

Another semiconductor chip 100 not employing a cooling structure may be disposed on a printed circuit board 1000. The another semiconductor chip 100 not employing the cooling structure may be packaged in a separate housing, or may be also packaged in one housing together with the semiconductor chip 100 with the cooling structure. The semiconductor chip 100 not employing the cooling structure may be sealed to prevent a contact with a cooling fluid. This structure may also be applied to the embodiments of the semiconductor apparatus 1 shown in FIGS. 1 to 14. A plurality of semiconductor chips 100 may be also arranged in a transverse direction. For example, in the embodiment of the semiconductor apparatus 1 shown in FIG. 1, two or more semiconductor chips 100 may be also arranged in the transverse direction.

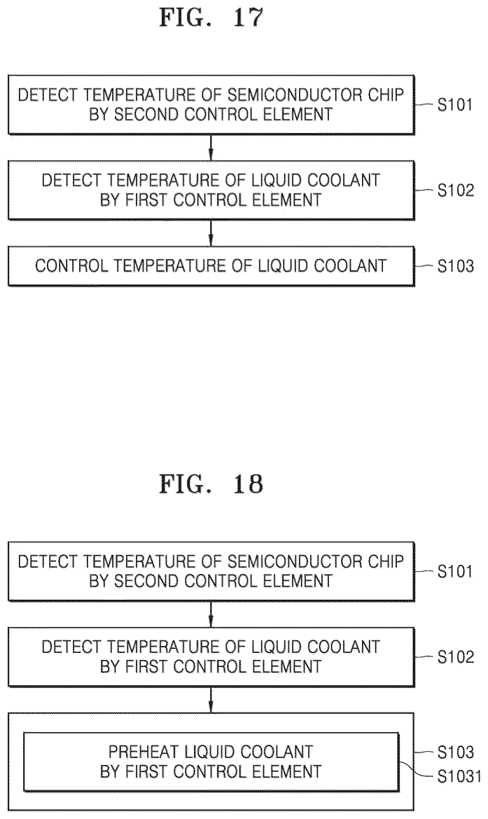

FIG. 17 is a flowchart illustrating a method of controlling a temperature of a liquid coolant in a semiconductor apparatus according to an embodiment. FIG. 18 is a flowchart illustrating a method of controlling a temperature of a liquid coolant in a semiconductor apparatus according to an embodiment

Referring to FIGS. 17 and 18, the method of controlling the temperature of the liquid coolant LC of the semiconductor apparatus 1 according to some embodiments may include a method of controlling a temperature of a liquid coolant LC supplied to a cooling channel 10 that is formed in a semiconductor chip 100 and has a fine pattern 20 forming a capillary pressure inducing a flow of the liquid coolant LC.

The method of controlling the temperature of the liquid coolant LC of the semiconductor apparatus 1 according to some embodiments may include operation S101 of detecting, by a second control element 52 of a temperature controller 50, whether a temperature of the semiconductor chip 100 is greater than or equal to a critical temperature.

Operation S101 of detecting, by the second control element 52, whether the temperature of the semiconductor chip 100 is greater than or equal to the critical temperature may include the operation of detecting, by the second control element 52, a thermal load of the semiconductor chip 100. Operation S101 of detecting, by the second control element 52, whether the temperature of the semiconductor chip 100 is greater than or equal to the critical temperature may include the operation of detecting, by the second control element 52, a temperature of a semiconductor integrated circuit 120. Operation S101 of detecting, by the second control element 52, whether the temperature of the semiconductor chip 100 is greater than or equal to the critical temperature may include the operation of providing the temperature controller 50 with information for determining a need for preheating, by the second control element 52, the liquid coolant LC.

The method of controlling the temperature of the liquid coolant LC of the semiconductor apparatus 1 according to some embodiments may include Operation S102 of detecting, by a first control element 51 of the temperature controller 50, the temperature of the liquid coolant LC supplied to the cooling channel 10.

Operation S102 of detecting, by the first control element 51, the temperature of the liquid coolant LC supplied to the cooling channel 10 may include the operation of detecting a saturation degree of the liquid coolant LC supplied to the cooling channel 10. Operation S102 of detecting, by the first control element 51, the temperature of the liquid coolant LC supplied to the cooling channel 10 may include the operation of determining, by the first control element 51, whether the temperature of the liquid coolant LC is less than or equal to a predefined temperature.

The method of controlling the temperature of the liquid coolant LC of the semiconductor apparatus 1 according to some embodiments may include Operation S103 of controlling, by the temperature controller 50, the temperature of the liquid coolant LC supplied to the cooling channel 10.

Operation S103 of controlling the temperature of the liquid coolant LC supplied to the cooling channel 10 according to some embodiments may include the operation of preheating, by the first control element 51, the liquid coolant LC supplied to the cooling channel 10. As shown in FIG. 18, operation S103 may include operation S1031, where the first control element 51 may preheat the liquid coolant LC such that the temperature of the liquid coolant LC supplied to the cooling channel 10 may reach a critical temperature. The first control element 51 may preheat the liquid coolant LC such that the temperature of the liquid coolant LC supplied to the cooling channel 10 may reach a boiling point temperature.

Some embodiments may provide a semiconductor apparatus having high heat exchange efficiency.

Some embodiments may provide a semiconductor apparatus having high integration.

The above-described embodiments are merely exemplary, and various modified and equivalent other embodiments may be made by those skilled in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor apparatus comprising:
a semiconductor chip comprising a semiconductor integrated circuit;
a cooling channel at least partially in the semiconductor chip and comprising a fine pattern on at least a portion of a wall surface of the cooling channel, the fine pattern configured to generate a capillary pressure that induces a flow of a liquid coolant; and
a temperature controller configured to control a supply temperature of the liquid coolant supplied to the cooling channel.

2. The semiconductor apparatus of claim 1, wherein the temperature controller comprises a heating element configured to preheat the liquid coolant supplied to the cooling channel.

3. The semiconductor apparatus of claim 1, wherein the temperature controller comprises a first control element configured to:
detect a temperature of the liquid coolant supplied to the cooling channel; and
based on the temperature of the liquid coolant being less than or equal to a predefined temperature, preheat the liquid coolant.

4. The semiconductor apparatus of claim 3, wherein the first control element comprises a resistance temperature sensor.

5. The semiconductor apparatus of claim 4, wherein the temperature controller further comprises a second control element configured to detect a temperature of the semiconductor integrated circuit.

6. The semiconductor apparatus of claim 5, wherein the temperature controller is further configured to preheat the liquid coolant supplied to the cooling channel based on the temperature of the semiconductor integrated circuit detected by the second control element being greater than or equal to a critical temperature.

7. The semiconductor apparatus of claim 6, wherein the critical temperature corresponds to a boiling point temperature of the liquid coolant.

8. The semiconductor apparatus of claim 7, wherein the temperature controller is further configured to heat the liquid coolant until the temperature of the liquid coolant supplied to the cooling channel reaches the critical temperature.

9. The semiconductor apparatus of claim 1, further comprising:
a liquid channel region in a region of the cooling channel where the fine pattern is formed, the liquid channel region being configured as a passage for the liquid coolant; and
a vapor channel region in a remaining region of the cooling channel where the fine pattern is not formed, the vapor channel region configured as a passage for a vapor coolant.

10. The semiconductor apparatus of claim 9, further comprising a package housing at least partially surrounding the semiconductor chip,
wherein the package housing comprises a first opening configured to discharge the vapor coolant from the cooling channel and at least one second opening configured to supply the liquid coolant to the cooling channel.

11. The semiconductor apparatus of claim 9, further comprising a vapor chamber disposed on the semiconductor chip and comprising at least a portion of the fine pattern for forming the cooling channel.

12. The semiconductor apparatus of claim 11, wherein the vapor chamber exposes at least a portion of the semiconductor chip to the cooling channel.

13. The semiconductor apparatus of claim 12, wherein the temperature controller is disposed between the semiconductor chip and the vapor chamber.

14. A semiconductor apparatus comprising:
a semiconductor chip comprising a semiconductor integrated circuit;
a plurality of cooling channels at least partially in the semiconductor chip, each of the plurality of cooling channels comprising a fine pattern on at least a portion of a wall surface of a respective cooling channel of the plurality of cooling channels, each of the fine patterns being configured to generate a capillary pressure that induces a flow of a liquid coolant; and
a temperature controller configured to control a supply temperature of the liquid coolant supplied to the plurality of cooling channels.

15. The semiconductor apparatus of claim 14, further comprising a package housing at least partially surrounding the semiconductor chip, the package housing comprising at least one first opening configured to discharge vapor coolant and a plurality of second openings respectively corresponding to the plurality of cooling channels and configured to apply the liquid coolant to respective cooling channels of the plurality of cooling channels.

16. A method of controlling a temperature of a liquid coolant supplied to a cooling channel in a semiconductor chip, the cooling channel comprising a fine pattern configured to generate a capillary pressure that induces a flow of the liquid coolant, the method comprising:
detecting, by a first control element of a temperature controller, the temperature of the liquid coolant supplied to the cooling channel; and
controlling, by the temperature controller, the temperature of the liquid coolant supplied to the cooling channel.

17. The method of claim 16, further comprising, prior to the detecting the temperature of the liquid coolant, detecting, by a second control element of the temperature controller, whether a temperature of the semiconductor chip greater than or equal to a critical temperature.

18. The method of claim 17, wherein the controlling the temperature of the liquid coolant comprises preheating, by the first control element, the liquid coolant supplied to the cooling channel.

19. The method of claim 18, wherein the preheating the liquid coolant comprises preheating, by the first control element, the liquid coolant such that the temperature of the liquid coolant supplied to the cooling channel reaches the critical temperature.

20. The method of claim 19, wherein the critical temperature corresponds to a boiling point temperature of the liquid coolant.
